(19) United States
(12) Patent Application Publication
(10) Pub. No.: US 2026/0026235 A1
(43) Pub. Date: Jan. 22, 2026

(54) DISPLAY DEVICE, OPTICAL DEVICE, ELECTRONIC DEVICE, AND METHOD FOR MANUFACTURING THE DISPLAY DEVICE

(71) Applicant: Samsung Display Co., Ltd., Yongin-si (KR)

(72) Inventors: Young Min KIM, Yongin-si (KR); Soon Kyeong KWON, Yongin-si (KR); Hyun Woo NOH, Yongin-si (KR); Hyun Suk PARK, Yongin-si (KR); Moon Jung BAEK, Yongin-si (KR); Dae Ho LEE, Yongin-si (KR); Su Ji HAN, Yongin-si (KR)

(21) Appl. No.: 19/268,586

(22) Filed: Jul. 14, 2025

(30) Foreign Application Priority Data
Jul. 17, 2024 (KR) 10-2024-0094678
Jan. 23, 2025 (KR) 10-2025-0010420

(51) Int. Cl. H10K 59/80; H10K 59/12; H10K 59/122

(52) U.S. Cl. CPC H10K 59/80518; H10K 59/1201; H10K 59/122; H10K 59/80517

(57) ABSTRACT

A display device includes: a substrate; a first intermediate connection electrode, a second intermediate connection electrode, and a third intermediate connection electrode disposed on the substrate; a planarization layer disposed on the first intermediate connection electrode, the second intermediate connection electrode, and the third intermediate connection electrode; a first reflective electrode, a second reflective electrode, and a third reflective electrode disposed on the planarization layer; a first step layer disposed on the first reflective electrode, the second reflective electrode, and the third reflective electrode; a first anode electrode disposed on the first step layer overlapping the first reflective electrode; a bank disposed on the first anode electrode; a light-emitting stack disposed on the first anode electrode and the bank; and a cathode electrode disposed on the light-emitting stack.

### CROSS-REFERENCE TO RELATED APPLICATIONS

The present application claims priority to and the benefits of Korean Patent Application No. 10-2024-0094678, filed on Jul. 17, 2024, in the Korean Intellectual Property Office, and Korean Patent Application No. 10-2025-0010420 filed on Jan. 23, 2025, in the Korean Intellectual Property Office, the content of each of which is incorporated herein by reference.

### BACKGROUND

### 1. Field

The present disclosure relates to a display device, for example, a display device, an optical device, an electronic device, and a method for manufacturing the same in which an aperture ratio of a pixel may be improved.

### 2. Description of the Related Art

Organic light-emitting diode (OLED) displays have self-luminous properties and do not require separate light sources, unlike liquid crystal displays. Therefore, the organic light-emitting diode displays may have reduced thickness and weight. In addition, the organic light-emitting diode displays have attracted attention for utilization in next-generation display devices, such as televisions (TVs), monitors, and/or portable electronic devices, because the organic light-emitting diode displays exhibit high-quality characteristics such as low power consumption, high luminance, and/or high response speed.

### SUMMARY

Aspects of one or more embodiments of the present disclosure provide a display device, an optical device, an electronic device, and a method for manufacturing the same that enhance (e.g., improve) an aperture ratio of a pixel.

However, aspects of one or more embodiments of the present disclosure are not restricted to those set forth herein. The above and other aspects of one or more embodiments of the present disclosure will become more apparent to one of ordinary skill in the art to which the present disclosure pertains by referencing the detailed descriptions of the present disclosure.

According to one or more embodiments of the present disclosure, a display device may include: a substrate; a first intermediate connection electrode, a second intermediate connection electrode, and a third intermediate connection electrode arranged on the substrate; a planarization layer arranged on the first intermediate connection electrode, the second intermediate connection electrode, and the third intermediate connection electrode; a first reflective electrode, a second reflective electrode, and a third reflective electrode arranged on the planarization layer; a first step layer arranged on the first reflective electrode, the second reflective electrode, and the third reflective electrode; a first anode electrode arranged on the first step layer overlapping the first reflective electrode; a bank arranged on the first anode electrode; a light-emitting stack arranged on the first anode electrode and the bank; and a cathode electrode arranged on the light-emitting stack. The first anode electrode may be in contact with an upper surface of the first intermediate connection electrode, an upper surface of the first reflective electrode, and a side surface of the first reflective electrode through a first contact hole may penetrate through the first step layer and the planarization layer.

In one or more embodiments, in plan view, the first contact hole may be surrounded and defined by the planarization layer, the first step layer, and the first reflective electrode.

In one or more embodiments, the first contact hole may have a first width arranged on a lower side of the first reflective electrode, and the first contact hole may have a second width arranged on an upper side of the first reflective electrode, the second width being greater than the first width.

In one or more embodiments, the display device may further include a second step layer arranged on the first step layer overlapping the second reflective electrode and the third reflective electrode, and a second anode electrode arranged on the second step layer overlapping the second reflective electrode and the first step layer. The second anode electrode may be in contact with an upper surface of the second intermediate connection electrode, an upper surface of the second reflective electrode, and a side surface of the second reflective electrode through a second contact hole penetrating through the second step layer, the first step layer, and the planarization layer.

In one or more embodiments, in plan view, the second contact hole may be surrounded and defined by the planarization layer, the first step layer, the second step layer, and the second reflective electrode.

In one or more embodiments, the display device may further include a third step layer arranged on the second step layer overlapping the third reflective electrode, and a third anode electrode arranged on the third step layer overlapping the third reflective electrode, the first step layer, and the second step layer. The third anode electrode may be in contact with an upper surface of the third intermediate connection electrode, an upper surface of the third reflective electrode, and a side surface of the third reflective electrode through a third contact hole penetrating through the third step layer, the second step layer, the first step layer, and the planarization layer.

In one or more embodiments, in plan view, the third contact hole may be surrounded and defined by the planarization layer, the first step layer, the second step layer, the third step layer, and the third reflective electrode.

In one or more embodiments, the first contact hole, the second contact hole, and the third contact hole may have different depths.

In one or more embodiments, a depth of the second contact hole may be greater than a depth of the first contact hole and smaller than a depth of the third contact hole.

In one or more embodiments, a distance from the first reflective electrode to the cathode electrode, a distance from the second reflective electrode to the cathode electrode, and a distance from the third reflective electrode to the cathode electrode may be different from each other.

In one or more embodiments, the distance from the second reflective electrode to the cathode electrode is greater than the distance from the first reflective electrode to the cathode electrode, and the distance from the second reflective electrode to the cathode electrode may be smaller than the distance from the third reflective electrode to the cathode electrode.

In one or more embodiments, the display device may further include a first color filter overlapping the first anode electrode and the first reflective electrode, a second color filter overlapping the second anode electrode and the second reflective electrode, and a third color filter overlapping the third anode electrode and the third reflective electrode.

In one or more embodiments, the first color filter may be configured to selectively transmit light of a red wavelength, the second color filter may be configured to selectively transmit light of a green wavelength, and the third color filter may be configured to selectively transmit light of a blue wavelength.

In one or more embodiments, the first anode electrode, the second anode electrode, and the third anode electrode are at different heights arranged on the planarization layer.

In one or more embodiments, a distance from the planarization layer to the second anode electrode may be greater than a distance from the planarization layer to the first anode electrode, and the distance from the planarization layer to the second anode electrode may be smaller than a distance from the planarization layer to the third anode electrode.

In one or more embodiments, the first anode electrode, the second anode electrode, and the third anode electrode may have the same thickness.

In one or more embodiments, the first step layer, the second step layer, and the third step layer may have the same thickness.

According to one or more embodiments of the present disclosure, an optical device may include a display device and an optical path conversion member arranged on the display device. The display device may include: a substrate; a first intermediate connection electrode, a second intermediate connection electrode, and a third intermediate connection electrode arranged on the substrate; a planarization layer arranged on the first intermediate connection electrode, the second intermediate connection electrode, and the third intermediate connection electrode; a first reflective electrode, a second reflective electrode, and a third reflective electrode arranged on the planarization layer; a first step layer arranged on the first reflective electrode, the second reflective electrode, and the third reflective electrode; a first anode electrode arranged on the first step layer overlapping the first reflective electrode; a bank arranged on the first anode electrode; a light-emitting stack arranged on the first anode electrode and the bank; and a cathode electrode arranged on the light-emitting stack.

The first anode electrode may be in contact with an upper surface of the first intermediate connection electrode, an upper surface of the first reflective electrode, and a side surface of the first reflective electrode through a first contact hole penetrating through the first step layer and the planarization layer.

In one or more embodiments, in plan view, the first contact hole may be surrounded and defined by the planarization layer, the first step layer, and the first reflective electrode.

In one or more embodiments, the first contact hole may have a first width on a lower side of the first reflective electrode, and the first contact hole may have a second width on an upper side of the first reflective electrode, where the second width may be greater than the first width.

In one or more embodiments, the display device may further include: a second step layer arranged on the first step layer overlapping the second reflective electrode and the third reflective electrode; and a second anode electrode arranged on the second step layer overlapping the second reflective electrode and the first step layer, and the second anode electrode may be in contact with an upper surface of the second intermediate connection electrode, an upper surface of the second reflective electrode, and a side surface of the second reflective electrode through a second contact hole penetrating through the second step layer, the first step layer, and the planarization layer.

In one or more embodiments, the display device may further include: a third step layer arranged on the second step layer overlapping the third reflective electrode; and a third anode electrode arranged on the third step layer overlapping the third reflective electrode, the first step layer, and the second step layer, and the third anode electrode may be in contact with an upper surface of the third intermediate connection electrode, an upper surface of the third reflective electrode, and a side surface of the third reflective electrode through a third contact hole penetrating through the third step layer, the second step layer, the first step layer, and the planarization layer.

According to one or more embodiments of the present disclosure, a method may include: forming a first intermediate connection electrode, a second intermediate connection electrode, and a third intermediate connection electrode on a substrate; forming a planarization layer on the first intermediate connection electrode, the second intermediate connection electrode, and the third intermediate connection electrode; forming a first reflective electrode, a second reflective electrode, and a third reflective electrode on the planarization layer; forming a first step layer on the first reflective electrode, the second reflective electrode, and the third reflective electrode; forming a first contact hole by patterning the first step layer and the planarization layer, the first contact hole exposing an upper surface of the first intermediate connection electrode, an upper surface of the first reflective electrode, and a side surface of the first reflective electrode; forming a first anode electrode on the first step layer, the first anode electrode being in contact with the upper surface of the first intermediate connection electrode, the upper surface of the first reflective electrode, and the side surface of the first reflective electrode through the first contact hole; forming a bank on the first anode electrode; forming a light-emitting stack on the first anode electrode and the bank; and forming a cathode electrode on the light-emitting stack. The method may be a method for manufacturing a display device.

In one or more embodiments, the method may further include: forming a second step layer on the first step layer and the first anode electrode; forming a second contact hole and forming the second step layer on the first step layer overlapping the second reflective electrode and the third reflective electrode by patterning the second step layer, the first step layer, and the planarization layer, the second contact hole exposing an upper surface of the second intermediate connection electrode, an upper surface of the second reflective electrode, and a side surface of the second reflective electrode; and forming a second anode electrode on the second step layer, the second anode electrode being in contact with the upper surface of the second intermediate connection electrode, the upper surface of the second reflective electrode, and the side surface of the second reflective electrode through the second contact hole.

In one or more embodiments, the method may further include: forming a third step layer on the second step layer, the first anode electrode, and the second anode electrode; forming a third contact hole and forming the third step layer on the second step layer overlapping the third reflective electrode by patterning the third step layer, the second step layer, the first step layer, and the planarization layer, the third contact hole exposing an upper surface of the third intermediate connection electrode, an upper surface of the third reflective electrode, and a side surface of the third reflective electrode; and forming a third anode electrode on the third step layer, the third anode electrode being in contact with the upper surface of the third intermediate connection electrode, the upper surface of the third reflective electrode, and the side surface of the third reflective electrode through the third contact hole.

In one or more embodiments, each of the first step layer, the second step layer, and the third step layer may include an inorganic film.

According to one or more embodiments of the present disclosure, an electronic device may include a display device providing a display screen. The display device may include: a substrate; a first intermediate connection electrode, a second intermediate connection electrode, and a third intermediate connection electrode disposed on the substrate; a planarization layer disposed on the first intermediate connection electrode, the second intermediate connection electrode, and the third intermediate connection electrode; a first reflective electrode, a second reflective electrode, and a third reflective electrode disposed on the planarization layer; a first step layer disposed on the first reflective electrode, the second reflective electrode, and the third reflective electrode; a first anode electrode disposed on the first step layer overlapping the first reflective electrode; a bank disposed on the first anode electrode; a light-emitting stack disposed on the first anode electrode and the bank; and a cathode electrode disposed on the light-emitting stack. The first anode electrode may be in contact with an upper surface of the first intermediate connection electrode, an upper surface of the first reflective electrode, and a side surface of the first reflective electrode through a first contact hole penetrating through the first step layer and the planarization layer.

In one or more embodiments, the electronic device may include a smartphone, a tablet personal computer (PC), a laptop computer, a television (TV), a monitor for a desktop computer, smart glasses, a smart watch, a head-mounted display, and/or a vehicle.

With a display device, an optical device, an electronic device, and a method for manufacturing the same according to one or more embodiments, an aperture ratio of a pixel may be improved.

For example, a reflective electrode constitutes a portion of an inner wall of a contact hole, and thus, a reflective electrode, an anode electrode, and an intermediate connection electrode may be in contact with and connected to each other through only one contact hole. Accordingly, the number of contact holes for connecting the reflective electrode, the anode electrode, and the intermediate connection electrode may be reduced, such that an aperture ratio of the pixel may be improved.

In addition, anode electrodes adjacent to each other are arranged at different heights on different layers, and it is thus possible for the anode electrodes adjacent to each other in a horizontal direction to be arranged more closely to each other. For example, an area of the anode electrode and an area of an emission area may be further expanded in the horizontal direction. Accordingly, an aperture ratio of the pixel may be improved or increased which allows more light to emit, and therefore, a high-resolution display device may be implemented.

The effects of the present disclosure are not limited to the above-described effects and other effects which are not described herein will become apparent to those skilled in the art from the following description.

For example, the described method and device aim to improve the aperture ratio of a pixel by reducing the number of contact holes needed for connections, allowing for closer arrangement of anode electrodes at different heights, thus expanding the emission area and enabling high-resolution displays. The effects of the present disclosure are not limited to these improvements and other benefits will become apparent to those skilled in the art.

### BRIEF DESCRIPTION OF THE DRAWINGS

The above and other aspects and features of the present disclosure will become more apparent by describing in more detail embodiments thereof with reference to the attached drawings, in which:

FIG. 1 is a perspective view illustrating a display device according to one or more embodiments;

FIG. 2 is a cross-sectional view illustrating the display device according to one or more embodiments;

FIG. 3 is a plan view illustrating a display of the display device according to one or more embodiments;

FIG. 4 is a block diagram illustrating a display panel and a display driver according to one or more embodiments;

FIG. 5 is a cross-sectional view of the display device according to one or more embodiments;

FIG. 6 is an enlarged view of area A of FIG. 5;

FIG. 7 is a view illustrating a state in which a first anode electrode, a bank, and a light-emitting stack are removed from FIG. 6;

FIG. 8 is a view illustrating a state in which components on a third anode electrode are removed from FIG. 5;

FIGS. 9-18 are cross-sectional views each for describing processes of a method for manufacturing a display device according to one or more embodiments;

FIG. 19 is a perspective view illustrating a head-mounted display device according to one or more embodiments;

FIG. 20 is an exploded perspective view illustrating an example of the head-mounted display device of FIG. 19;

FIG. 21 is a perspective view illustrating a head-mounted display according to one or more embodiments;

FIG. 22 is a block diagram of an electronic device according to one or more embodiments; and

FIGS. 23-25 are schematic views each showing electronic devices according to one or more suitable embodiments.

### DETAILED DESCRIPTION

The present disclosure will now be described more fully hereinafter with reference to the accompanying drawings, in which one or more embodiments of present disclosure are shown, and duplicative descriptions thereof may not be provided. The present disclosure may, however, be embodied in different forms and should not be construed as limited to one or more embodiments set forth herein.

Rather, these embodiments are provided so that the present disclosure will be thorough and complete, and will fully convey the scope of present disclosure and equivalents thereof to those skilled in the art.

As utilized herein, the term “and/or” includes any and all combinations of one or more of the associated listed items. Throughout the disclosure, the expression “at least one of a, b or c” indicates only a, only b, only c, both (e.g., simultaneously) a and b, both (e.g., simultaneously) a and c, both (e.g., simultaneously) b and c, all of a, b, and c, or variations thereof.

In the present disclosure, it will be understood that the term “comprise(s)/comprising,” “include(s)/including,” or “have/has/having” specifies the presence of stated features, integers, steps, operations, elements, and/or components, but do not preclude the presence or addition of one or more other features, integers, steps, operations, elements, components, and/or groups thereof. Additionally, the terms “comprise(s)/comprising,” “include(s)/including,” “have/has/having” or similar terms include or support the terms “consisting of” and “consisting essentially of,” indicating the presence of stated features, integers, steps, operations, elements, and/or components, without or essentially without the presence of other features, integers, steps, operations, elements, components, and/or groups thereof.

The singular forms “a,” “an,” and “the” as utilized herein are intended to include the plural forms as well unless the context clearly indicates otherwise.

It will also be understood that if (e.g., when) an element or layer is referred to as being “on,” “connected to,” “coupled to,” or “adjacent to” another element, layer, or substrate, it can be directly on, connected to, coupled to, or adjacent to the other element, layer, or substrate, or one or more intervening elements or layers, or substrates may also be present. In contrast, when an element or layer is referred to as being “directly on,” “directly connected to”, “directly coupled to”, or “immediately adjacent to” another element or layer, there are no intervening elements or layers present.

The x-axis, the y-axis and the z-axis are not limited to three axes of the rectangular coordinate system, and may be interpreted in a broader sense. For example, the x-axis, the y-axis, and the z-axis may be normal (e.g., perpendicular) to one another, or may represent different directions that are not normal (e.g., perpendicular) to one another.

Further, in this specification, the phrase “on a plane,” or “plan view,” indicates viewing a target portion from the top, and the phrase “on a cross-section” indicates viewing a cross-section formed by vertically cutting a target portion from the side.

The same reference numbers indicate the same components throughout the specification. In the attached drawings, the thickness of layers and regions is exaggerated for clarity.

Although the terms “first”, “second”, and/or the like may be utilized herein to describe one or more suitable elements, these elements, should not be limited by these terms. These terms may be utilized to distinguish one element from another element. Thus, a first element discussed may be termed a second element without departing from teachings of one or more embodiments. The description of an element as a “first” element may not require or imply the presence of a second element or other elements. The terms “first”, “second”, and/or the like may also be utilized herein to differentiate different categories or sets of elements. For conciseness, the terms “first”, “second”, and/or the like may represent “first-category (or first-set)”, “second-category (or second-set)”, and/or the like, respectively.

Features of one or more suitable embodiments of the present disclosure may be combined partially or totally. As will be clearly appreciated by those skilled in the art, technically one or more suitable interactions and operations are possible. One or more suitable embodiments may be practiced individually and/or in combination.

Hereinafter, one or more embodiments will be described in more detail with reference to the accompanying drawings, where like reference numerals refer to like elements throughout, and duplicative descriptions thereof may not be provided, and a repeated description thereof is omitted. Sizes of elements in the drawings may be exaggerated or reduced for convenience of explanation. In some embodiments, the size and thickness of each element shown in the drawings are arbitrarily represented for convenience of description, and thus, the disclosure is not necessarily limited thereto. The same reference numeral indicates the same component throughout the specification.

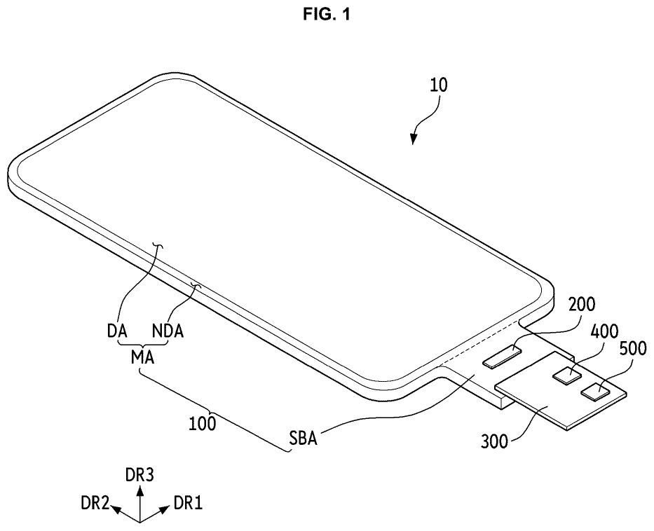

FIG. 1 is a perspective view illustrating a display device according to one or more embodiments.

Referring to FIG. 1, a display device 10 may be applied to portable electronic devices, such as mobile phones, smartphones, tablet personal computers (PCs), mobile communication terminals, electronic notebooks, electronic books, portable multimedia players (PMPs), navigation devices, and/or ultra mobile PCs (UMPCs). For example, the display device 10 may be applied as a display of televisions, laptop computers, monitors, billboards, and/or the Internet of Things (IOTs). In one or more embodiments, the display device 10 may be applied to wearable devices, such as smart watches, watch phones, glasses-type (kind) displays, and/or head-mounted displays (HMDs).

The display device 10 may have a shape similar to a rectangular shape in plan view. For example, the display device 10 may have a shape similar to a rectangular shape, in plan view, having short sides in a first direction DR1 and long sides in a second direction DR2. A corner where the short side in the first direction DR1 and the long side in the second direction DR2 meet may be rounded with a selected curvature and/or right-angled. The shape of the display device 10 in plan view is not limited to a rectangular shape or a shape similar to the rectangular shapr, and may be a shape similar to other polygonal shapes, a circular shape, and/or an elliptical shape.

The display device 10 may include a display panel 100, a display driver 200, a circuit board 300, a touch driver 400, and a power supply (e.g., a power supply unit) 500.

The display panel 100 may include a main area MA and a sub-area SBA.

The main area MA may include a display area DA including pixels displaying an image and a non-display area NDA arranged around (e.g., disposed around) the display area DA. The display area DA may be to emit light from a plurality of emission areas and/or a plurality of opening areas. For example, the display panel 100 may include pixel circuits including switching elements, a pixel defining film defining the plurality of emission areas or the plurality of opening areas, and self-light-emitting elements.

For example, the self-light-emitting element may include at least one of an organic light-emitting diode (LED) including an organic light-emitting layer, a quantum dot LED including a quantum dot light-emitting layer, an inorganic LED including an inorganic semiconductor, and/or a micro LED, but the present disclosure is not limited thereto.

The non-display area NDA may be an area outside the display area DA. The non-display area NDA may be defined as an edge area of the main area MA of the display panel 100. The non-display area NDA may include a gate driver supplying gate signals to gate lines and fan-out lines connecting the display driver 200 and the display area DA to each other.

The sub-area SBA may be extended from one side of the main area MA. The sub-area SBA may include a flexible material that may be bent, folded, and/or rolled. For example, if (e.g., when) the sub-area SBA is bent, the sub-area SBA may be overlapped with the main area MA in a thickness direction (e.g., a third direction DR3) (e.g., the bent sub-area SBA may be on the main area MA in the third direction DR3). The sub-area SBA may include the display driver 200 and pad portions connected to the circuit board 300. In one or more embodiments, the sub-area SBA may not be provided, and the display driver 200 and the pad portions may be arranged in (e.g., disposed in) the non-display area NDA.

The display driver 200 may be configured to output signals and voltages for driving the display panel 100. The display driver 200 may be configured to supply data voltages to data lines. The display driver 200 may be configured to supply source voltages to power lines and supply gate control signals to the gate driver. The display driver 200 may be formed as an integrated circuit (IC) and mounted on the display panel 100 in a chip on glass (COG) manner, a chip on plastic (COP) manner, and/or an ultrasonic bonding manner. For example, the display driver 200 may be arranged in the sub-area SBA, and may be configured to overlap the main area MA in the thickness direction (third direction DR3) by bending of the sub-area SBA. In one or more embodiments, the display driver 200 may be mounted on the circuit board 300.

The circuit board 300 may be attached onto the pad portions of the display panel 100 utilizing an anisotropic conductive film (ACF). Lead lines of the circuit board 300 may be electrically connected to the pad portions of the display panel 100. The circuit board 300 may be a flexible printed circuit board, a printed circuit board, and/or a flexible film such as a chip on film.

The touch driver 400 may be mounted on the circuit board 300. The touch driver 400 may be electrically connected to a touch sensing unit (e.g., a touch sensor) of the display panel 100. The touch driver 400 may be configured to supply touch driving signals to a plurality of touch electrodes of the touch sensing unit and sense change amounts in capacitance between the plurality of touch electrodes. For example, the touch driving signal may be a pulse signal having a selected frequency. The touch driver 400 may decide whether or not an input has occurred and calculate input coordinates, based on the change amounts in capacitance between the plurality of touch electrodes. The touch driver 400 may be formed as an integrated circuit (IC).

The power supply 500 may be arranged on the circuit board 300 and may be configured to supply source voltages to the display driver 200 and the display panel 100. The power supply 500 may generate a driving voltage to a driving voltage line VDL, initialization voltages (e.g., a first initialization voltage and a second initialization voltage) to initialization voltage lines (e.g., a first initialization voltage line VIL1 and a second initialization voltage line VIL2), and a common voltage to a common electrode (e.g., a cathode electrode) common to light-emitting elements of a plurality of pixels. For example, the driving voltage may be a high-potential voltage for driving the light-emitting element, and the common voltage may be a low-potential voltage for driving the light-emitting element.

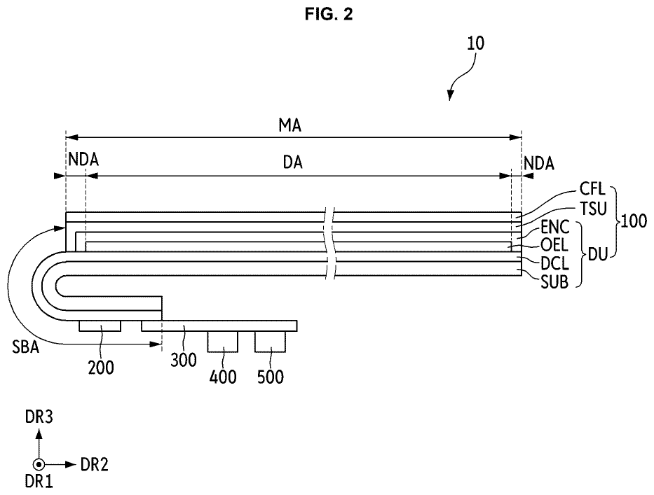

FIG. 2 is a cross-sectional view illustrating the display device according to one or more embodiments.

Referring to FIG. 2, the display panel 100 may include a display unit (e.g., a display) DU, a touch sensing unit (e.g., a touch sensor) TSU, and a color filter layer CFL. The display unit DU may include a substrate SUB, a driving circuit layer DCL, an optical element layer OEL, and an encapsulation layer ENC.

The driving circuit layer DCL may be arranged on the substrate SUB. The driving circuit layer DCL may include a plurality of transistors (e.g., thin-film transistors) constituting pixel circuits of the pixels. The driving circuit layer DCL may further include gate lines, data lines, power lines, gate control lines, fan-out lines connecting the display driver 200 and the data lines to each other, and lead lines connecting the display driver 200 and the pad portions to each other.

The driving circuit layer DCL may be arranged in the display area DA, the non-display area NDA, and the sub-area SBA. The transistors of each of the pixels, the gate lines, the data lines, and the power lines of the driving circuit layer DCL may be arranged in the display area DA. The gate control lines and the fan-out lines of the driving circuit layer DCL may be arranged in the non-display area NDA. The lead lines of the driving circuit layer DCL may be arranged in the sub-area SBA.

The optical element layer OEL may be arranged on the driving circuit layer DCL. The optical element layer OEL may include a plurality of light-emitting elements in which a pixel electrode (e.g., an anode electrode), a light-emitting layer, and a common electrode (e.g., a cathode electrode) are sequentially stacked to emit light and a bank defining the pixels. The plurality of light-emitting elements of the optical element layer OEL may be arranged in the display area DA.

The light-emitting layer may be an organic light-emitting layer including an organic material. The light-emitting layer may include a hole transporting layer, an organic light-emitting layer, and an electron transporting layer. If (e.g., when) the pixel electrode receives a selected voltage through the transistor of the driving circuit layer DCL and the common electrode receives a cathode voltage, holes and electrons may be moved to the organic light-emitting layer through the hole transporting layer and the electron transporting layer, respectively, and may be combined with each other in the organic light-emitting layer to emit light (e.g., holes and electrons may be combined to emit light).

In one or more embodiments, the plurality of light-emitting elements may include quantum dot light-emitting diodes each including a quantum dot light-emitting layer, inorganic light-emitting diodes each including an inorganic semiconductor, and/or micro light-emitting diodes.

The encapsulation layer ENC may be configured to cover an upper surface and side surfaces of the optical element layer OEL, and may protect the optical element layer OEL. The encapsulation layer ENC may include at least one inorganic film and at least one organic film for encapsulating the optical element layer OEL.

The touch sensing unit TSU may be arranged on the encapsulation layer ENC. The touch sensing unit TSU may include a plurality of touch electrodes for sensing a user's touch in a capacitance manner and touch lines connecting the plurality of touch electrodes and the touch driver 400 to each other. For example, the touch sensing unit TSU may be configured to sense the user's touch in a mutual capacitance manner and/or a self-capacitance manner.

In one or more embodiments, the touch sensing unit TSU may be arranged on a separate substrate arranged on the display unit DU. In this case, the substrate supporting the touch sensing unit TSU may be a base member encapsulating the display unit DU.

The plurality of touch electrodes of the touch sensing unit TSU may be arranged in a touch sensor area overlapping the display area DA. The touch lines of the touch sensing unit TSU may be arranged in a touch peripheral area overlapping the non-display area NDA.

The color filter layer CFL may be arranged on the touch sensing unit TSU. The color filter layer CFL may include a plurality of color filters respectively corresponding to the plurality of emission areas. Each of the plurality of color filters may selectively transmit light of a specific wavelength and block or absorb light of other wavelengths. The color filter layer CFL may be to absorb some of light introduced from the outside of the display device 10 to reduce reflected light by external light. Accordingly, the color filter layer CFL may prevent or reduce distortion of colors due to external light reflection.

Because the color filter layer CFL is directly arranged on the touch sensing unit TSU, the display device 10 may not require a separate substrate for the color filter layer CFL. Accordingly, a thickness of the display device 10 may be relatively decreased.

The sub-area SBA of the display panel 100 may be extended from one side of the main area MA. The sub-area SBA may include a flexible material that may be bent, folded, and/or rolled. For example, if (e.g., when) the sub-area SBA is bent, the sub-area SBA may be configured to overlap the main area MA in the thickness direction (e.g., the third direction DR3). The sub-area SBA may include the display driver 200 and the pad portions connected to the circuit board 300.

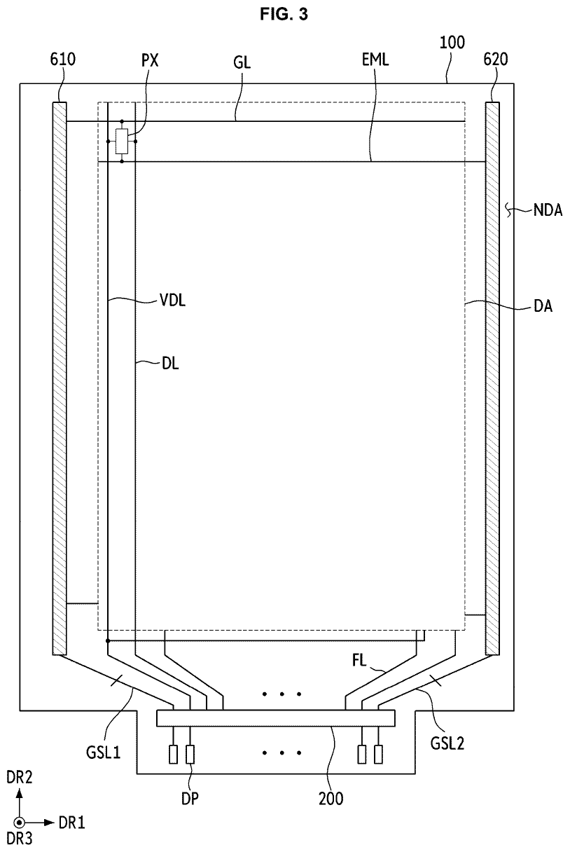

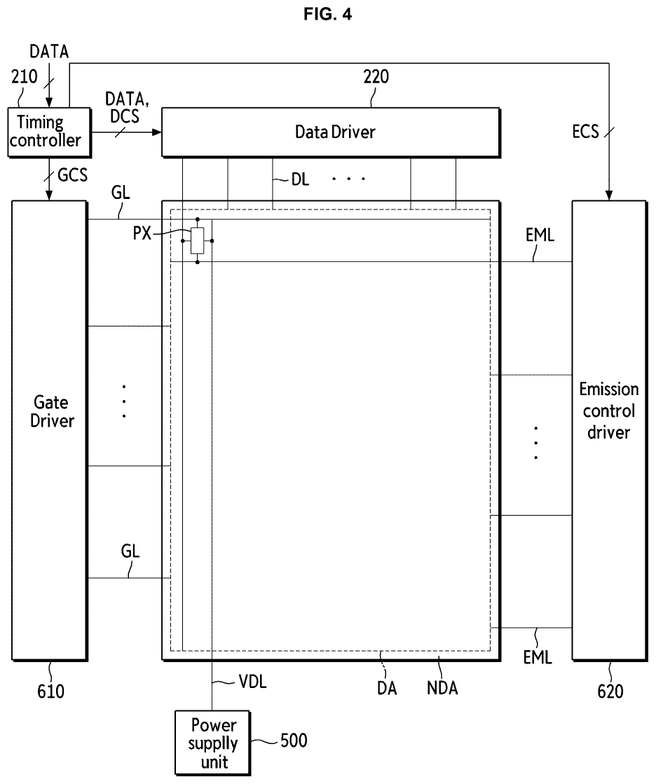

FIG. 3 is a plan view illustrating a display of the display device according to one or more embodiments, and FIG. 4 is a block diagram illustrating a display panel and a display driver according to one or more embodiments.

Referring to FIGS. 3 and 4, the display panel 100 may include a display area DA and a non-display area NDA.

The display area DA may include a plurality of pixels PX, a plurality of driving voltage lines VDL connected to the plurality of pixels PX, and a plurality of gate lines GL, a plurality of emission control lines EML, and a plurality of data lines DL of a plurality of common voltage lines.

Each of the plurality of pixels PX may be connected to the gate line GL, the data line DL, the emission control line EML, the driving voltage line VDL, and the common voltage line. Each of the plurality of pixels PX may include at least one transistor, a light-emitting element, and/or a capacitor.

The plurality of gate lines GL may be extended in the first direction DR1, and may be spaced and/or apart (e.g., spaced apart or separated) from each other in the second direction DR2 crossing the first direction DR1. The plurality of gate lines GL may be arranged along the second direction DR2. The plurality of gate lines GL may sequentially supply gate signals to the plurality of pixels PX.

The plurality of emission control lines EML may be extended in the first direction DR1, and may be spaced and/or apart (e.g., spaced apart or separated) from each other in the second direction DR2. The plurality of emission control lines EML may be arranged along the second direction DR2. The plurality of emission control lines EML may be configured to sequentially supply emission signals to the plurality of pixels PX.

The plurality of data lines DL may be extended in the second direction DR2, and may be spaced and/or apart (e.g., spaced apart or separated) from each other in the first direction DR1. The plurality of data lines DL may be arranged along the first direction DR1. The plurality of data lines DL may supply data voltages to the plurality of pixels PX. The data voltage may determine luminance of each of the plurality of pixels PX.

The plurality of driving voltage lines VDL may be extended in the second direction DR2, and may be spaced and/or apart (e.g., spaced apart or separated) from each other in the first direction DR1. The plurality of driving voltage lines VDL may be arranged along the first direction DR1. The plurality of driving voltage lines VDL may supply a first driving voltage to the plurality of pixels PX. The first driving voltage may be a high-potential voltage for driving the light-emitting elements of the plurality of pixels PX.

The non-display areas NDA may be around (e.g., surround) the display area DA. The non-display area NDA may include a gate driver 610, an emission control driver 620, fan-out lines FL, a first gate control line GSL1, and a second gate control line GSL2.

The fan-out lines FL may be extended from the display driver 200 to the display area DA. The fan-out lines FL may be configured to supply the data voltages received from the display driver 200 to the plurality of data lines DL.

The first gate control line GSL1 may be extended from the display driver 200 to the gate driver 610. The first gate control line GSL1 may be configured to supply a gate control signal GCS received from the display driver 200 to the gate driver 610.

The second gate control line GSL2 may be extended from the display driver 200 to the emission control driver 620. The second gate control line GSL2 may be configured to supply an emission control signal ECS received from the display driver 200 to the emission control driver 620.

The sub-area SBA may be extended from one side of the non-display area NDA. The sub-area SBA may include the display driver 200 and pad portions DP. The pad portion DP may be located more adjacent to an edge of one side of the sub-area SBA than the display driver 200 is. The pad portion DP may be electrically connected to the circuit board 300 through an anisotropic conductive film (ACF).

The display driver 200 may include a timing controller 210 and a data driver 220.

The timing controller 210 may be configured to receive digital video data DATA and timing signals from the circuit board 300. The timing controller 210 may be configured to control an operation timing of the data driver 220 by generating a data control signal DCS based on the timing signals, to control an operation timing of the gate driver 610 by generating the gate control signal GCS based on the timing signals, and to control an operation timing of the emission control driver 620 by generating the emission control signal ECS based on the timing signals. The timing controller 210 may be configured to supply the gate control signal GCS to the gate driver 610 through the first gate control line GSL1. The timing controller 210 may be configured to supply the emission control signal ECS to the emission control driver 620 through the second gate control line GSL2. The timing controller 210 may be configured to supply the digital video data DATA and the data control signal DCS to the data driver 220.

The data driver 220 may be configured to convert the digital video data DATA into analog data voltages and supply the analog data voltages to the plurality of data lines DL through the fan-out lines FL. Gate signals of the gate driver 610 may be configured to select a plurality of pixels PX to which the data voltages are supplied, and the selected plurality of pixels PX may be configured to receive the data voltages through the plurality of data lines DL.

The power supply 500 may be arranged on the circuit board 300, and may be configured to supply source voltages to the display driver 200 and the display panel 100. The power supply 500 may generate a driving voltage to the driving voltage line VDL, an initialization voltage to an initialization voltage line, and a common voltage to a common electrode common to light-emitting elements of the plurality of pixels. For example, the power supply 500 may generate the driving voltage and supply it to the driving voltage line VDL. Furthermore, the power supply 500 may generate the initialization voltage and supply it to the initialization voltage line. The power supply 500 may also generate the common voltage and supply it to the common electrode that is common to the light-emitting elements of the plurality of pixels.

The gate driver 610 may be arranged outside one side of the display area DA or on one side of the non-display area NDA, and the emission control driver 620 may be arranged outside the other side of the display area DA or on the other side of the non-display area NDA, but the present disclosure is not limited thereto. In one or more embodiments, the gate driver 610 and the emission control driver 620 may be arranged on any one of one side and the other side of the non-display area NDA.

The gate driver 610 may include a plurality of transistors generating gate signals based on the gate control signal GCS. The emission control driver 620 may include a plurality of transistors generating emission signals based on the emission control signal ECS. For example, the transistors of the gate driver 610 and the transistors of the emission control driver 620 may be formed at a same layer as the transistors of each of the plurality of pixels PX. The gate driver 610 may be configured to supply the gate signals to the plurality of gate lines GL, and the emission control driver 620 may be configured to supply the emission signals to the plurality of emission control lines EML.

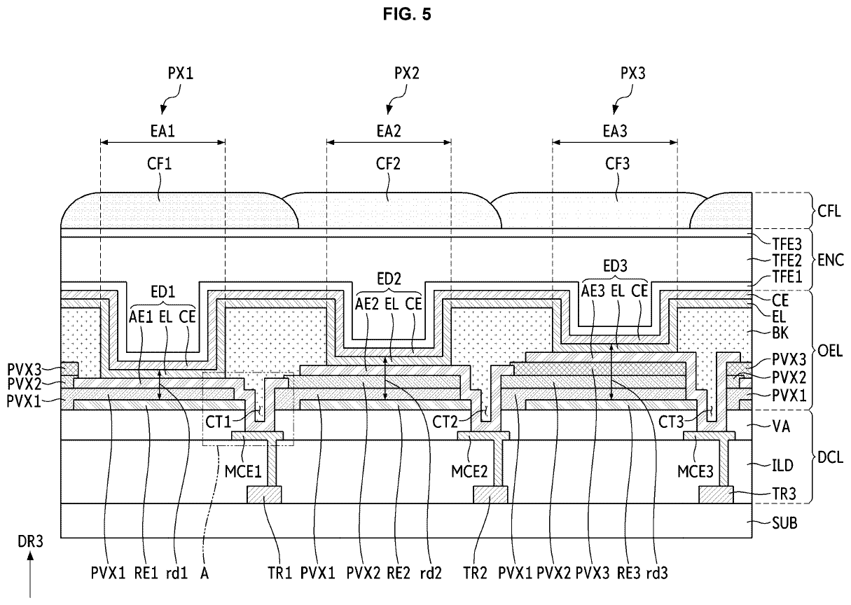

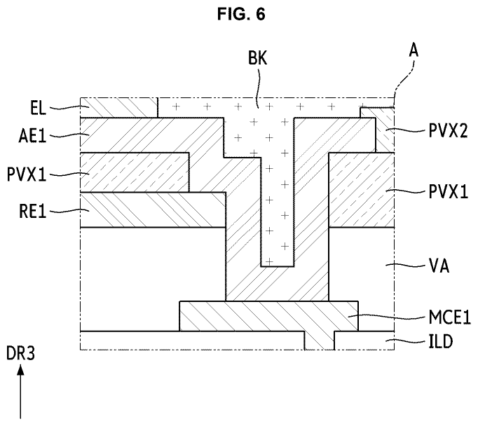

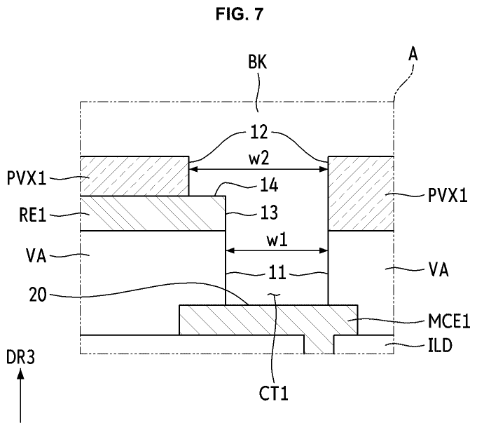

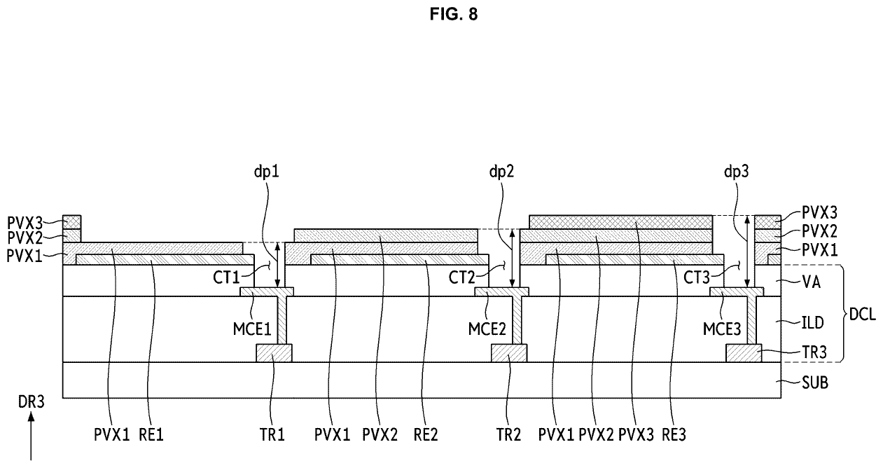

FIG. 5 is a cross-sectional view of the display device 10 according to one or more embodiments. For example, FIG. 5 may be a cross-sectional view of the display area DA of the display device 10 illustrated in FIG. 1. FIG. 6 is an enlarged view of area A of FIG. 5, FIG. 7 is a view illustrating a state in which a first anode electrode AE1, a bank, and a light-emitting stack are removed from FIG. 6, and FIG. 8 is a view illustrating a state in which components on a third anode electrode AE3 are removed from FIG. 5.

In one or more embodiments, the display device 10 may include a first pixel PX1, a second pixel PX2, and a third pixel PX3 that provide light of different colors, as illustrated in FIG. 5. The first pixel PX1, the second pixel PX2, and the third pixel PX3 may be located adjacent to each other to constitute a unit pixel providing one unit image. For example, the unit pixel (e.g., a pixel group) may include the first pixel PX1, the second pixel PX1, and the third pixel PX3 and provide a unit image.

The first pixel PX1 may include a first transistor TR1, a first intermediate connection electrode MCE1, a first reflective electrode RE1, a first step layer PVX1, a first light-emitting element ED1, and a first color filter CF1.

The second pixel PX2 may include a second transistor TR2, a second intermediate connection electrode MCE2, a second reflective electrode RE2, a first step layer PVX1, a second step layer PVX2, a second light-emitting element ED2, and a second color filter CF2.

The third pixel PX3 may include a third transistor TR3, a third intermediate connection electrode MCE3, a third reflective electrode RE3, a first step layer PVX1, a second step layer PVX2, a third step layer PVX3, a third light-emitting element ED3, and a third color filter CF3.

In one or more embodiments, the display device 10 may include a substrate SUB, a driving circuit layer DCL, an optical element layer OEL, an encapsulation layer ENC, and a color filter layer CFL, as illustrated in FIG. 5.

The substrate SUB may be a base substrate and/or a base member. The substrate SUB may be a flexible substrate that may be bent, folded, and/or rolled. For example, the substrate SUB may include a polymer resin such as polyimide (PI), but the present disclosure is not limited thereto. In one or more embodiments, the substrate SUB may include a glass material and/or a metal material.

The driving circuit layer DCL may be arranged on the substrate SUB. The driving circuit layer DCL may include a plurality of transistors TR1, TR2, and TR3. For example, the driving circuit layer DCL may include the first transistor TR1, the second transistor TR2, the third transistor TR3, an interlayer insulating layer ILD, the first intermediate connection electrode MCE1, the second intermediate connection electrode MCE2, the third intermediate connection electrode MCE3, and a planarization layer VA. In addition, the driving circuit layer DCL may further include the plurality of gate lines GL, the plurality of data lines DL, the power lines, the gate control lines, the fan-out lines FL, and the lead lines connecting the display driver 200 and the pad portion to each other.

The interlayer insulating layer ILD may be arranged on the first transistor TR1, the second transistor TR2, and the third transistor TR3. The interlayer insulating layer ILD may include an inorganic film such as a silicon nitride layer, a silicon oxynitride layer, a silicon oxide layer, a titanium oxide layer, and/or an aluminum oxide layer. In one or more embodiments, the display device 10 may include a plurality of interlayer insulating layers ILD arranged between the transistors TR1 to TR3 and the planarization layer VA.

The first intermediate connection electrode MCE1, the second intermediate connection electrode MCE2, and the third intermediate connection electrode MCE3 may be arranged on the interlayer insulating layer ILD. The first intermediate connection electrode MCE1 may be connected to a drain electrode of the first transistor TR1 through a contact hole penetrating through the interlayer insulating layer ILD. The second intermediate connection electrode MCE2 may be connected to a drain electrode of the second transistor TR2 through another contact hole penetrating through the interlayer insulating layer ILD. The third intermediate connection electrode MCE3 may be connected to a drain electrode of the third transistor TR3 through yet another contact hole penetrating through the interlayer insulating layer ILD.

The planarization layer VA may be arranged on the first intermediate connection electrode MCE1, the second intermediate connection electrode MCE2, the third intermediate connection electrode MCE3, and the interlayer insulating layer ILD. The planarization layer VA may be (e.g., be formed as) an organic film including (e.g., being made of) an acrylic resin, an epoxy resin, a phenolic resin, a polyamide resin, a polyimide resin, and/or the like.

The optical element layer OEL may be arranged on the driving circuit layer DCL. For example, the optical element layer OEL may be arranged on the planarization layer VA. The optical element layer OEL may include the first reflective electrode RE1, the second reflective electrode RE2, the third reflective electrode RE3, the first step layer PVX1, the second step layer PVX2, the third step layer PVX3, the first light-emitting element, the second light-emitting element, the third light-emitting element, and a bank BK (or a pixel defining film).

The first reflective electrode RE1, the second reflective electrode RE2, and the third reflective electrode RE3 may be arranged on the planarization layer VA. Their respective reflective electrodes RE1, RE2, and RE3 may be arranged on the planarization layer VA to be overlapped with their respective emission areas EA1, EA2, and EA3. For example, the first reflective electrode RE1 may be arranged on the planarization layer VA to be overlapped with a first emission area EA1, the second reflective electrode RE2 may be arranged on the planarization layer VA to be overlapped with a second emission area EA2, and the third reflective electrode RE3 may be arranged on the planarization layer VA to be overlapped with a third emission area EA3.

The first reflective electrode RE1 may include a metal layer including a metal such as silver (Ag), magnesium (Mg), aluminum (AI), platinum (Pt), palladium (Pd), gold (Au), nickel (Ni), neodymium (Nd), iridium (Ir), chromium (Cr), and/or compounds thereof. In one or more embodiments, the first reflective electrode RE1 may further include metal oxide layers (e.g., transparent conductive oxide layers) located above and/or below (e.g., beneath) the metal layer. For example, the first reflective electrode RE1 may have a double-layer structure, such as a double-layer structure including a first layer of indium tin oxide (ITO) and a second layer of Ag, a double-layer structure including a first layer of Ag and a second layer of ITO, a double-layer structure including a first layer of ITO and a second layer of Mg, or a double-layer structure including a first layer of ITO and a second layer of MgF, and/or a triple-layer structure, such as a triple-layer structure including a first layer of ITO, a second layer of Ag, and a third layer of ITO. Each of the second reflective electrode RE2 and the third reflective electrode RE3 may include (e.g., be made of) the same material as the first reflective electrode RE1 described above.

At least one step layer (or insulating layer) may be arranged on their respective reflective electrodes RE1, RE2, and RE3. For example, different numbers of step layers PVX1, PVX2, and PVX3 may be arranged along the third direction DR3 on their respective reflective electrodes RE1, RE2, and RE3. For example, the first step layer PVX1 may be arranged on the first reflective electrode RE1, the first step layer PVX1 and the second step layer PVX2 may be arranged on the second reflective electrode RE2, and the first step layer PVX1, the second step layer PVX2, and the third step layer PVX3 may be arranged on the third reflective electrode RE3.

The first step layer PVX1 may be overlapped with the first reflective electrode RE1, the second reflective electrode RE2, and the third reflective electrode RE3. The second step layer PVX2 may be overlapped with the second reflective electrode RE2 and the third reflective electrode RE3. The third step layer PVX3 may be overlapped with the third reflective electrode RE3. The second step layer PVX2 may be arranged between the first step layer PVX1 and the third step layer PVX3.

The first terminal layer PVX1, the second step layer PVX2, and the third step layer PVX3 may have the same thickness. In one or more embodiments, at least two of the first to third step layers PVX1 to PVX3 may have different thicknesses. Here, the thickness may be a size in the third direction DR3.

The first step layer PVX1 may be (e.g., be formed as) an inorganic film. For example, the first step layer PVX1 may be a silicon carbonitride (SiCN) and/or silicon oxide (SiOₓ (e.g., 0<x≤2))-based inorganic film (e.g., a high-transmissivity inorganic film). Each of the second step layer PVX2 and the third step layer PVX3 may include (e.g., be made of) the same material as the first step layer PVX1 described above.

The first light-emitting element ED1, the second light-emitting element ED2, and the third light-emitting element ED3 may be arranged on their respective step layers PVX1, PVX2, and PVX3. For example, the first light-emitting element ED1 may be arranged on the first step layer PVX1 in the first emission area EA1, the second light-emitting element ED2 may be arranged on the second step layer PVX2 in the second emission area EA2, and the third light-emitting element ED3 may be arranged on the third step layer PVX3 in the third emission area EA3.

The first light-emitting element ED1 may include a first anode electrode AE1, a light-emitting stack EL, and a cathode electrode CE. The first emission area EA1 may be an area where the first anode electrode AE1, the light-emitting stack EL, and the cathode electrode CE are sequentially stacked, and holes from the first anode electrode AE1 and electrons from the cathode electrode CE are combined with each other in the light-emitting stack EL to emit light.

The second light-emitting element ED2 may include a second anode electrode AE2, a light-emitting stack EL, and a cathode electrode CE. The second emission area EA2 may be an area where the second anode electrode AE2, the light-emitting stack EL, and the cathode electrode CE are sequentially stacked, and holes from the second anode electrode AE2 and electrons from the cathode electrode CE are combined with each other in the light-emitting stack EL to emit light.

The third light-emitting element ED3 may include a third anode electrode AE3, a light-emitting stack EL, and a cathode electrode CE. The third emission area EA3 may be an area where the third anode electrode AE3, the light-emitting stack EL, and the cathode electrode CE are sequentially stacked, and holes from the third anode electrode AE3 and electrons from the cathode electrode CE are combined with each other in the light-emitting stack EL to emit light.

The first anode electrode AE1 may be arranged on the first step layer PVX1. For example, the first anode electrode AE1 may be arranged on the first step layer PVX1 to be overlapped with the first reflective electrode RE1 and the first step layer PVX1 in the third direction DR3 in the first emission area EA1. The first step layer PVX1 may be arranged between the first reflective electrode RE1 and the first anode electrode AE1. The first anode electrode AE1 may be connected to the first intermediate connection electrode MCE1 and the first reflective electrode RE1 through a first contact hole CT1 penetrating through the first step layer PVX1 and the planarization layer VA. For example, the first contact hole CT1 may be configured to expose a portion of an upper surface 20 of the first intermediate connection electrode MCE1, a portion of an upper surface 14 of the first reflective electrode RE1, and a portion (or at least a portion) of a side surface 13 of the first reflective electrode RE1, and accordingly, the first anode electrode AE1 may be in contact with each of the first intermediate connection electrode MCE1 and the first reflective electrode RE1 within one first contact hole CT1. For example, the first anode electrode AE1 may not only be in contact with the upper surface 20 of the first intermediate connection electrode MCE1 but may also be in contact with the upper surface 14 and the side surface 13 of the first reflective electrode RE1, utilizing one first contact hole CT1. From another perspective, it may be considered that a portion of an inner wall of the first contact hole CT1 is constituted of the first reflective electrode RE1, and accordingly, the first anode electrode AE1 may be in contact with the first reflective electrode RE1 within the first contact hole CT1. For example, the first anode electrode AE1 may be in contact with the inner wall defining the first contact hole CT1 utilizing the first contact hole CT1, and a portion of the inner wall of the first contact hole CT1 may be the upper surface and the side surface of the first reflective electrode RE1. This will be described in more detail with reference to FIGS. 6 and 7.

For example, as illustrated in FIG. 7, the first contact hole CT1 may be defined by the planarization layer VA, the first step layer PVX1, and the first reflective electrode RE1. For example, in plan view, the inner wall of the first contact hole CT1 may be defined as an area surrounded by side surfaces 11 of the planarization layer VA, side surfaces 12 of the first step layer PVX1, the side surface 13 of the first reflective electrode RE1, and the upper surface 14 of the first reflective electrode RE1. The first anode electrode AE1 may be in contact (or in direct contact) with the side surfaces 11 of the planarization layer VA, the side surfaces 12 of the first step layer PVX1, the side surface 13 of the first reflective electrode RE1, and the upper surface 14 of the first reflective electrode RE1 within the first contact hole CT1, as illustrated in FIGS. 6 and 7. In addition, the first anode electrode AE1 may be in contact (or in direct contact) with the upper surface 20 of the first intermediate connection electrode MCE1 within the first contact hole CT1.

The first contact hole CT1 may have different widths. For example, the first contact hole CT1 may have a first width w1 on the lower side of the first reflective electrode RE1 and have a second width w2 on the upper side of the first reflective electrode RE1. The first width w1 may be defined as a distance between the side surfaces 11 of the planarization layer VA defining the inner wall of the first contact hole CT1, and the second width w2 may be defined as a distance between the side surfaces 12 of the first step layer PVX1 defining the inner wall of the first contact hole CT1. The second width w2 may be greater than the first width w1. Accordingly, a portion of the side surface 13 of the first reflective electrode RE1 and a portion of the upper surface 14 of the first reflective electrode RE1 may be exposed through the first contact hole CT1.

In a top emission structure in which light is emitted toward the cathode electrode CE based on the light-emitting stack EL, the first anode electrode AE1 may be (e.g., be formed as) a single layer made of molybdenum (Mo), titanium (Ti), copper (Cu), and/or aluminum (AI) or formed as a stacked structure (Ti/AI/Ti) of aluminum and titanium (e.g., a stacked structure including a layer of Ti, a layer of Al, and a layer of Ti), a stacked structure (ITO/Al/ITO) of aluminum and ITO (e.g., a stacked structure of a layer of ITO, a layer of Al, and a layer of ITO), an APC alloy, and a stacked structure (ITO/APC/ITO) of an APC alloy and ITO (e.g., a stacked structure of a layer of ITO, a layer of APC, and a layer of ITO) to increase reflectivity. The APC alloy is an alloy of silver (Ag), palladium (Pd), and copper (Cu). In addition, the first anode electrode AE1 may include (e.g., be made of) a material including a transparent conductive material (TCO) that is transparent and has a low extinction coefficient, such as ITO and/or indium zinc oxide (IZO).

The second anode electrode AE2 may be arranged on the second step layer PVX2. For example, the second anode electrode AE2 may be arranged on the second step layer PVX2 to be overlapped with the second reflective electrode RE2, the first step layer PVX1, and the second step layer PVX2 in the third direction DR3 in the second emission area EA2. The first step layer PVX1 and the second step layer PVX2 may be arranged between the second reflective electrode RE2 and the second anode electrode AE2. The second anode electrode AE2 may be connected to the second intermediate connection electrode MCE2 and the second reflective electrode RE2 through a second contact hole CT2 penetrating through the second step layer PVX2, the first step layer PVX1, and the planarization layer VA. For example, the second contact hole CT2 may be configured to expose a portion of an upper surface of the second intermediate connection electrode MCE2, a portion of an upper surface of the second reflective electrode RE2, and a portion (or at least a portion) of a side surface of the second reflective electrode RE2, and accordingly, the second anode electrode AE2 may be in contact with each of the second intermediate connection electrode MCE2 and the second reflective electrode RE2 within one second contact hole CT2. For example, the second anode electrode AE2 may not only be in contact with the upper surface of the second intermediate connection electrode MCE2 but may also be in contact with the upper surface and the side surface of the second reflective electrode RE2, utilizing one second contact hole CT2. From another perspective, it may be considered that a portion of an inner wall of the second contact hole CT2 is constituted of the second reflective electrode RE2, and accordingly, the second anode electrode AE2 may be in contact with the second reflective electrode RE2 within the second contact hole CT2. For example, the second anode electrode AE2 may be in contact with the inner wall defining the second contact hole CT2 utilizing the second contact hole CT2, and a portion of the inner wall of the second contact hole CT2 may be the upper surface and the side surface of the second reflective electrode RE2.

The second contact hole CT2 may be defined by the planarization layer VA, the first step layer PVX1, the second step layer PVX2, and the second reflective electrode RE2. For example, in plan view, the inner wall of the second contact hole CT2 may be defined as an area surrounded by side surfaces of the planarization layer VA, side surfaces of the first step layer PVX1, side surfaces of the second step layer PVX2, the side surface of the second reflective electrode RE2, and the upper surface of the second reflective electrode RE2. The second anode electrode AE2 may be in contact (or in direct contact) with the side surfaces of the planarization layer VA, the side surfaces of the first step layer PVX1, the side surfaces of the second step layer PVX2, the side surface of the second reflective electrode RE2, and the upper surface of the second reflective electrode RE2 within the second contact hole CT2. In addition, the second anode electrode AE2 may be in contact (or in direct contact) with the upper surface of the second intermediate connection electrode MCE2 within the second contact hole CT2.

The second contact hole CT2 may have different widths. For example, the second contact hole CT2 may have a first width on the lower side of the second reflective electrode RE2 and have a second width on the upper side of the second reflective electrode RE2. The first width may be defined as a distance between the side surfaces of the planarization layer VA defining the inner wall of the second contact hole CT2, and the second width may be defined as a distance between the side surfaces of the step layers PVX1 and PVX2 defining the inner wall of the second contact hole CT2. The second width may be greater than the first width. Accordingly, a portion of the side surface of the second reflective electrode RE2 and a portion of the upper surface of the second reflective electrode RE2 may be exposed through the second contact hole CT2.

The second anode electrode AE2 may include (e.g., be made of) the same material as the first anode electrode AE1 described above.

The third anode electrode AE3 may be arranged on the third step layer PVX3. For example, the third anode electrode AE3 may be arranged on the third step layer PVX3 to be overlapped with the third reflective electrode RE3, the first step layer PVX1, the second step layer PVX2, and the third step layer PVX3 in the third direction DR3 in the third emission area EA3. The first step layer PVX1, the second step layer PVX2, and the third step layer PVX3 may be arranged between the third reflective electrode RE3 and the third anode electrode AE3. The third anode electrode AE3 may be connected to the third intermediate connection electrode MCE3 and the third reflective electrode RE3 through a third contact hole CT3 penetrating through the third step layer PVX3, the second step layer PVX2, the first step layer PVX1, and the planarization layer VA. For example, the third contact hole CT3 may be configured to expose a portion of an upper surface of the third intermediate connection electrode MCE3, a portion of an upper surface of the third reflective electrode RE3, and a portion (or at least a portion) of a side surface of the third reflective electrode RE3, and accordingly, the third anode electrode AE3 may be in contact with each of the third intermediate connection electrode MCE3 and the third reflective electrode RE3 within one third contact hole CT3. For example, the third anode electrode AE3 may not only be in contact with the upper surface of the third intermediate connection electrode MCE3 but may also be in contact with the upper surface and the side surface of the third reflective electrode RE3, utilizing one third contact hole CT3. From another perspective, it may be considered that a portion of an inner wall of the third contact hole CT3 is constituted of the third reflective electrode RE3, and accordingly, the third anode electrode AE3 may be in contact with the third reflective electrode RE3 within the third contact hole CT3. For example, the third anode electrode AE3 may be in contact with the inner wall defining the third contact hole CT3 within the third contact hole CT3, and a portion of the inner wall of the third contact hole CT3 may be the upper surface and the side surface of the third reflective electrode RE3.

The third contact hole CT3 may be defined by the planarization layer VA, the first step layer PVX1, the second step layer PVX2, the third step layer PVX3, and the third reflective electrode RE3. For example, in plan view, the inner wall of the third contact hole CT3 may be defined as an area surrounded by side surfaces of the planarization layer VA, side surfaces of the first step layer PVX1, side surfaces of the second step layer PVX2, side surfaces of the third step layer PVX3, the side surface of the third reflective electrode RE3, and the upper surface of the third reflective electrode RE3. The third anode electrode AE3 may be in contact (or in direct contact) with the side surfaces of the planarization layer VA, the side surfaces of the first step layer PVX1, the side surfaces of the second step layer PVX2, the side surfaces of the third step layer PVX3, the side surface of the third reflective electrode RE3, and the upper surface of the third reflective electrode RE3 within the third contact hole CT3. In addition, the third anode electrode AE3 may be in contact (or in direct contact) with the upper surface of the third intermediate connection electrode MCE3 within the third contact hole CT3.

The third contact hole CT3 may have different widths. For example, the third contact hole CT3 may have a first width on the lower side of the third reflective electrode RE3 and have a second width on the upper side of the third reflective electrode RE3. The first width may be defined as a distance between the side surfaces of the planarization layer VA defining the inner wall of the third contact hole CT3, and the second width may be defined as a distance between the side surfaces of the step layers PVX1, PVX2, and PVX3 defining the inner wall of the third contact hole CT3. The second width may be greater than the first width. Accordingly, a portion of the side surface of the third reflective electrode RE3 and a portion of the upper surface of the third reflective electrode RE3 may be exposed through the third contact hole CT3.

The third anode electrode AE3 may include (e.g., be made of) the same material as the first anode electrode AE1 described above.

The first anode electrode AE1, the second anode electrode AE2, and the third anode electrode AE3 may be arranged at different heights. For example, a distance (hereinafter referred to as a first distance) from the planarization layer VA (or the first reflective electrode RE1) to the first anode electrode AE1 in the first emission area EA1, a distance (hereinafter referred to as a second distance) from the planarization layer VA (or the second reflective electrode RE2) to the second anode electrode AE2 in the second emission area EA2, and a distance (hereinafter referred to as a third distance) from the planarization layer VA (or the third reflective electrode RE3) to the third anode electrode AE3 in the third emission area EA3 may be different from each other. For example, the second distance may be greater than the first distance and smaller than the third distance. Here, each of the first distance, the second distance, and the third distance may be a size in the third direction DR3.

As described above, the first anode electrode AE1, the second anode electrode AE2, and the third anode electrode AE3 are arranged at different heights on different layers, and thus, the possibility of short-circuits between the anode electrodes adjacent to each other in a horizontal direction (e.g., the first direction DR1 or the second direction DR2) may be reduced. Accordingly, it is possible for the anode electrodes adjacent to each other in the horizontal direction to be arranged more closely to each other. For example, an area of the anode electrode and an area of the emission area may be further expanded in the horizontal direction. Accordingly, an aperture ratio of the pixel may be improved, and a high-resolution display device may be implemented.

The first anode electrode AE1, the second anode electrode AE2, and the third anode electrode AE3 may have the same thickness. Here, the thickness may be a size in the third direction DR3.

The first contact hole CT1, the second contact hole CT2, and the third contact hole CT3 may have different depths. For example, as illustrated in FIG. 8, a depth dp2 of the second contact hole CT2 may be greater than a depth dp1 of the first contact hole CT1 and smaller than a depth dp3 of the third contact hole CT3. Here, the depth (e.g., dp1) may be defined as a distance from a lower side of the contact hole (e.g., CT1) to an upper side of the contact hole (e.g., CT1) in the third direction DR3. Here, the lower side of the contact hole (e.g., CT1) may be arranged on the same line as the upper surface 20 of the corresponding intermediate connection electrode (e.g., MCE1), and the upper side of the contact hole (e.g., CT1) may be arranged on the same line as an upper surface of the uppermost step layer (e.g., PVX1) among the step layers arranged between the reflective electrode (e.g., RE1) and the anode electrode (e.g., AE1) connected to each other by the contact hole (e.g., CT1). Here, the uppermost step layer may be a step layer closer to the anode electrode of the reflective electrode and the anode electrode. For example, the uppermost step layer of the step layers PVX1, PVX2, and PVX3 between the third reflective electrode RE3 and the third anode electrode AE3 may be the third step layer PVX3.

As illustrated in FIG. 8, the lower side of the first contact hole CT1 may be arranged on the same line as the upper surface of the first intermediate connection electrode MCE1, and the upper side of the first contact hole CT1 may be arranged on the same line as an upper surface of the first step layer PVX1. The lower side of the second contact hole CT2 may be arranged on the same line as the upper surface of the second intermediate connection electrode MCE2, and the upper side of the second contact hole CT2 may be arranged on the same line as an upper surface of the second step layer PVX2. The lower side of the third contact hole CT3 may be arranged on the same line as the upper surface of the third intermediate connection electrode MCE3, and the upper side of the third contact hole CT3 may be arranged on the same line as an upper surface of the third step layer PVX3.

According to one or more embodiments, the reflective electrode (e.g., RE1), the anode electrode (e.g., AE1), and the intermediate connection electrode (e.g., MCE1) of one pixel (e.g., PX1) may be connected to each other through one contact hole (e.g., CT1). For example, the reflective electrode constitutes a portion of the inner wall of the contact hole, and thus, the reflective electrode, the anode electrode, and the intermediate connection electrode may be in contact with and connected to each other through only one contact hole. Accordingly, the number of contact holes for connecting the reflective electrode, the anode electrode, and the intermediate connection electrode to each other may be reduced, such that an aperture ratio of the pixel may be improved or increased.

The bank BK may define the emission areas EA1, EA2, and EA3 of the pixels PX1, PX2, and PX3. To this end, the bank BK may be configured to expose partial areas of the respective anode electrodes AE1, AE2, and AE3 on the step layers PVX1 to PVX3. The bank BK may be configured to cover edges of the respective anode electrodes AE1, AE2, and AE3. Each of the emission areas EA1, EA2, and EA3 may be a hole penetrating through the bank BK in the third direction DR3. The bank BK may be (e.g., be formed as) an organic film including (e.g., being made of) an acrylic resin, an epoxy resin, a phenolic resin, a polyamide resin, a polyimide resin, and/or the like.

The light-emitting stack EL may be arranged on the bank BK, the first anode electrode AE1, the second anode electrode AE2, and the third anode electrode AE3. The light-emitting stack EL may include a plurality of stack layers. For example, the light-emitting stack EL may have a three-tandem structure including a first stack layer, a second stack layer, and a third stack layer that are sequentially stacked along the third direction DR3. However, the present disclosure is not limited thereto, and the light-emitting stack EL may have, for example, a two-tandem structure including two stack layers.

In the three-tandem structure described above, the light-emitting stack EL may have a tandem structure including a plurality of stack layers that emits different light. For example, the light-emitting stack EL may include a first stack layer emitting light of a first color, a second stack layer emitting light of a second color, and a third stack layer emitting light of a third color. The first stack layer, the second stack layer, and the third stack layer may be sequentially stacked along the third direction DR3.

The first stack layer may have a structure in which a first hole transporting layer, a first organic light-emitting layer emitting the light of the first color, and a first electron transporting layer are sequentially stacked. The second stack layer may have a structure in which a second hole transporting layer, a second organic light-emitting layer emitting the light of the second color, and a second electron transporting layer are sequentially stacked. The third stack layer may have a structure in which a third hole transporting layer, a third organic light-emitting layer emitting the light of the third color, and a third electron transporting layer are sequentially stacked.

A first charge generation layer for supplying charges to the second stack layer and supplying electrons to the first stack layer may be arranged between the first stack layer and the second stack layer. The first charge generation layer may include an N-type (kind) charge generation layer supplying electrons to the first stack layer and a P-type (kind) charge generation layer supplying holes to the second stack layer. The N-type (kind) charge generation layer may include a dopant of a metal material.

A second charge generation layer for supplying charges to the third stack layer and supplying electrons to the second stack layer may be arranged between the second stack layer and the third stack layer. The second charge generation layer may include an N-type (kind) charge generation layer supplying electrons to the second stack layer and a P-type (kind) charge generation layer supplying holes to the third stack layer.

The first color, the second color, and the third color described above may be different colors. For example, one of the first color, the second color, and the third color may be a red color, another one of the first color, the second color, and the third color may be a green color, and the remaining one of the first color, the second color, and the third color may be a blue color. The light-emitting stack EL may provide light (e.g., white light) obtained by mixing the light of the first color from the first organic light-emitting layer, the light of the second color from the second organic light-emitting layer, and the light of the third color from the third organic light-emitting layer with each other. Accordingly, each of the light-emitting elements of the display device 10 including the first light-emitting element ED1, the second light-emitting element ED2, and the third light-emitting element ED3 may provide the white light.

The cathode electrode CE may be arranged on the light-emitting stack EL. The cathode electrode CE may cover the light-emitting stack EL. A capping layer may be further arranged on the cathode electrode CE.

In the top emission structure, the cathode electrode CE may include (e.g., be made of) a transparent conductive material (TCO) such as ITO and/or IZO capable of transmitting light and/or a semi-transmissive conductive material such as magnesium (Mg), silver (Ag), and/or an alloy of magnesium (Mg) and silver (Ag). If (e.g., when) the cathode electrode CE includes (e.g., is made of) the semi-transmissive conductive material, light emission efficiency may be increased by a micro cavity.

As illustrated in FIG. 5, the numbers of step layers PVX1 to PVX3 located in the respective emission areas EA1, EA2, and EA3 (e.g., the numbers of stacked step layers overlapping the respective emission areas EA1, EA2, and EA3 in the third direction DR3) are different from each other, and thus, distances between the reflective electrodes and the cathode electrode CE may be different from each other for each pixel.

For example, one step layers PVX1 may be arranged between the first reflective electrode RE1 and the first anode electrode AE1 in the first emission area EA1, two step layers PVX1 and PVX2 may be arranged between the second reflective electrode RE2 and the second anode electrode AE2 in the second emission area EA2, and three step layers PVX1, PVX2, and PVX3 may be arranged between the third reflective electrode RE3 and the third anode electrode AE3 in the third emission area EA3, and accordingly, a distance (hereinafter referred to as a fourth distance) between the first reflective electrode RE1 and the first anode electrode AE1 in the first emission area EA1, a distance (hereinafter referred to as a fifth distance) between the second reflective electrode RE2 and the second anode electrode AE2 in the second emission area EA2, and a distance (hereinafter referred to as a sixth distance) between the third reflective electrode RE3 and the third anode electrode AE3 in the third emission area EA3 may be different from each other. For example, the fifth distance may be greater than the fourth distance and smaller than the sixth distance.

Because the numbers of stacked step layers are different from each other for each pixel as described above, distances between the reflective electrodes and the anode electrodes may be different from each other for each emission area, and accordingly, resonance distances rd1, rd2, and rd3 between the reflective electrodes and the cathode electrode CE for each pixel may be adjusted to be different from each other. For example, a distance (hereinafter referred to as a first resonance distance rd1) between the first reflective electrode RE1 and the cathode electrode CE in the first emission area EA1, a distance (hereinafter referred to as a second resonance distance rd2) between the second reflective electrode RE2 and the cathode electrode CE in the second emission area EA2, and a distance (hereinafter referred to as a third resonance distance rd3) between the third reflective electrode RE3 and the cathode electrode CE in the third emission area EA3 may be different from each other. According to one or more embodiments, the second resonance distance rd2 may be greater than the first resonance distance rd1 and smaller than the third resonance distance rd3.

Accordingly, a micro-cavity (or thin-film resonance) effect on light may be increased and/or improved or optimized according to a wavelength of light to be emitted from each of the pixels PX1, PX2, and PX3 and a resonance distance, a resonance order, and/or the like, corresponding to the wavelength. For example, the light of the first color, the light of the second color, and the light of the third color may be appropriately or suitably amplified in the first emission area EA1, the second emission area EA2, and the third emission area EA3, respectively. In one or more embodiments, the light of the first color emitted through the first emission area EA1 may be red light corresponding to a first color filter CF1 to be described in more detail, the light of the second color emitted through the second emission area EA2 may be green light corresponding to a second color filter CF2 to be described in more detail, and the light of the third color emitted through the third emission area EA3 may be blue light corresponding to a third color filter CF3 to be described in more detail. For example, the resonance distance rd2 of the second emission area EA2 from which the green light is emitted may be greater than the resonance distance rd1 of the first emission area EA1 from which the red light is emitted and smaller than the resonance distance rd3 of the third emission area EA3 through which the blue light is emitted. However, the present disclosure is not limited thereto, and for example, the first color may correspond to one color of the above-described red color, green color, and blue color, the second color may correspond to another color of the above-described red color, green color, and blue color, and the third color may correspond to the remaining color of the above-described red color, green color, and blue color.

The encapsulation layer ENC may be on (e.g., be formed on) the optical element layer OEL. The encapsulation layer ENC may include at least one inorganic layer TFE1 or TFE3 to prevent or reduce oxygen and/or moisture from permeating into the optical element layer OEL. In addition, the encapsulation layer ENC may include at least one organic layer TFE2 to protect the optical element layer OEL from foreign substances such as dust. For example, the encapsulation layer ENC may include a first encapsulation inorganic layer TFE1, an encapsulation organic layer TFE2, and a second encapsulation inorganic layer TFE3.

The first encapsulation inorganic layer TFE1 may be arranged on the cathode electrode CE, the encapsulation organic layer TFE2 may be arranged on the first encapsulation inorganic layer TFE1, and the second encapsulation inorganic layer TFE3 may be arranged on the encapsulation organic layer TFE2. Each of the first encapsulation inorganic layer TFE1 and the second encapsulation inorganic layer TFE3 may be formed as multiple films in which one or more inorganic films of a silicon nitride layer, a silicon oxynitride layer, a silicon oxide layer, a titanium oxide layer, and/or an aluminum oxide layer are alternately stacked. The encapsulation organic layer TFE2 may be an organic film including an acrylic resin, an epoxy resin, a phenolic resin, a polyamide resin, a polyimide resin, and/or the like.

The color filter layer CFL may be arranged on the encapsulation layer ENC. The color filter layer CFL may include a plurality of color filters CF1, CF2, and CF3.

The first color filter CF1 may be overlapped with the first emission area EA1 of the first pixel PX1. The first color filter CF1 may be to transmit the light of the first color (e.g., light of a red wavelength band). Therefore, the first color filter CF1 may be to transmit the light of the first color among light emitted from the first emission area EA1.

The second color filter CF2 may be overlapped with the second emission area EA2 of the second pixel PX2. The second color filter CF2 may be to transmit the light of the second color (e.g., light of a green wavelength band). Therefore, the second color filter CF2 may be to transmit the light of the second color among light emitted from the second emission area EA2.

The third color filter CF3 may be overlapped with the third emission area EA3 of the third pixel PX3. The third color filter CF3 may be to transmit the light of the third color (e.g., light of a blue wavelength band). Therefore, the third color filter CF3 may be to transmit the light of the third color among light emitted from the third emission area EA3.

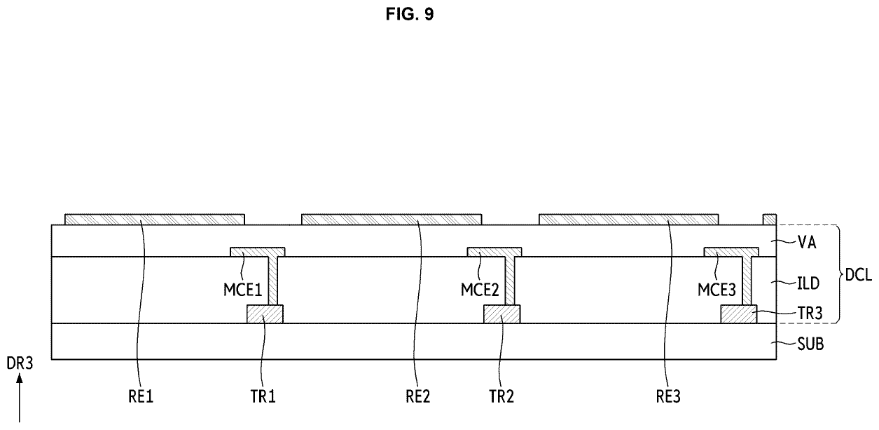

FIGS. 9 to 18 are cross-sectional views each showing processes of a method for manufacturing a display device according to one or more embodiments.

First, as illustrated in FIG. 9, the first transistor TR1, the second transistor TR2, and the third transistor TR3 may be formed on the substrate SUB. Thereafter, the interlayer insulating layer ILD may be formed on the first to third transistors TR1, TR2, and TR3. Next, contact holes penetrating through the interlayer insulating layer ILD and exposing the drain electrode of the first transistor TR1, the drain electrode of the second transistor TR2, and the drain electrode of the third transistor TR3, respectively, may be formed. Next, the first intermediate connection electrode MCE1, the second intermediate connection electrode MCE2, and the third intermediate connection electrode MCE3 may be formed on the interlayer insulating layer ILD. In this case, the first intermediate connection electrode MCE1 may be connected to the drain electrode of the first transistor TR1 through a contact hole of the interlayer insulating layer ILD, the second intermediate connection electrode MCE2 may be connected to the drain electrode of the second transistor TR2 through another contact hole of the interlayer insulating layer ILD, and the third intermediate connection electrode MCE3 may be connected to the drain electrode of the third transistor TR3 through yet another contact hole of the interlayer insulating layer ILD. The first to third intermediate connection electrodes MCE1, MCE2, and MCE3 may be concurrently (e.g., simultaneously) formed utilizing the same material. The first to third intermediate connection electrodes MCE1, MCE2, and MCE3 may have the same thickness. Thereafter, the planarization layer VA may be formed on the first to third intermediate connection electrodes MCE1, MCE2, and MCE3. Next, the first reflective electrode RE1, the second reflective electrode RE2, and the third reflective electrode RE3 may be formed on the planarization layer VA. The first reflective electrode RE1, the second reflective electrode RE2, and the third reflective electrode RE3 may be concurrently (e.g., simultaneously) formed utilizing the same material. The first reflective electrode RE1, the second reflective electrode RE2, and the third reflective electrode RE3 may have the same thickness.

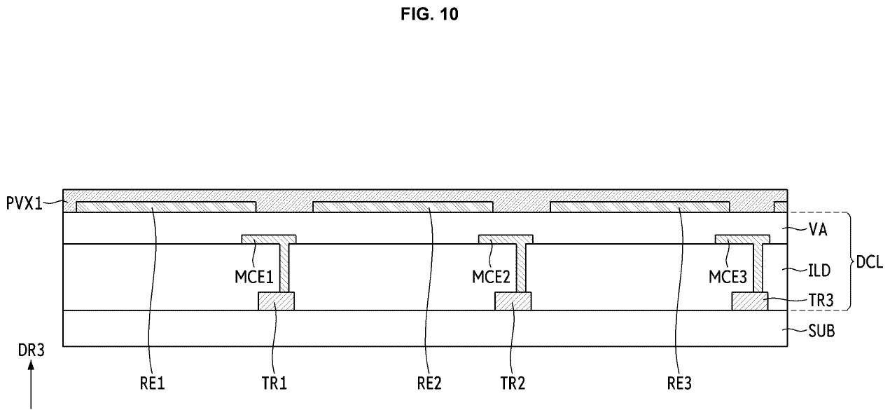

Thereafter, as illustrated in FIG. 10, the first step layer PVX1 may be formed on the planarization layer VA, the first reflective electrode RE1, the second reflective electrode RE2, and the third reflective electrode RE3. The first step layer PVX1 may be overlapped with each of the first reflective electrode RE1, the second reflective electrode RE2, and the third reflective electrode RE3.

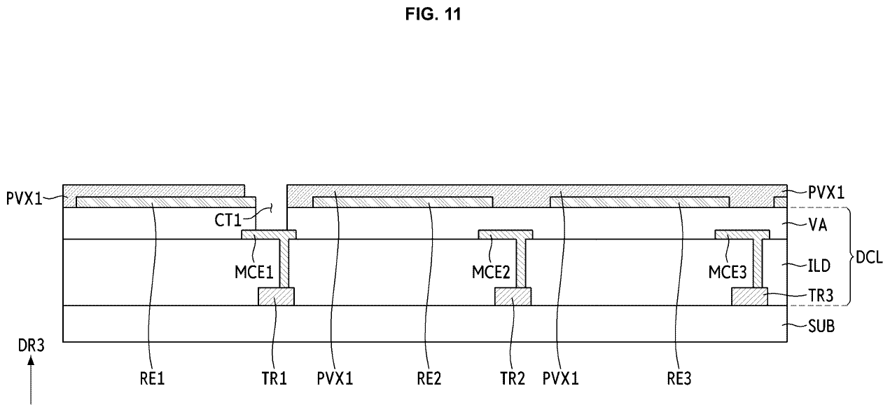

Subsequently, as illustrated in FIG. 11, the first contact hole CT1 penetrating through the first step layer PVX1 and the planarization layer VA may be formed. For example, the first contact hole CT1 may be formed by removing the first step layer PVX1 and the planarization layer VA by dry etching through a photolithography process. The upper surface of the first intermediate connection electrode MCE1, the side surface of the first reflective electrode RE1, and the upper surface of the first reflective electrode RE1 may be exposed by the first contact hole CT1.

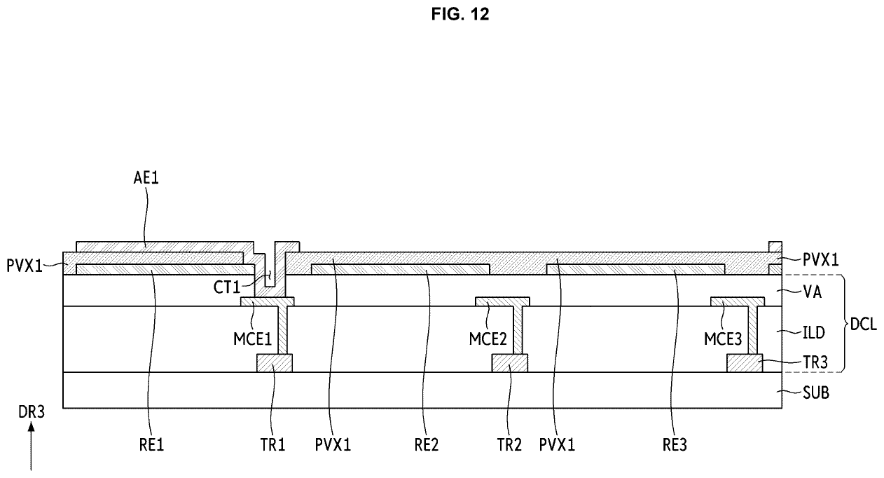

Next, as illustrated in FIG. 12, the first anode electrode AE1 may be formed on the first step layer PVX1. For example, the first anode electrode AE1 may be arranged on the first step layer PVX1 to be overlapped with the first step layer PVX1 and the first reflective electrode RE1. The first anode electrode AE1 may be connected to the first intermediate connection electrode MCE1 and the first reflective electrode RE1 through the first contact hole CT1. For example, the first anode electrode AE1 may be in contact (or in direct contact) with each of the upper surface 20 of the first intermediate connection electrode MCE1, the side surface 13 of the first reflective electrode RE1, and the upper surface 14 of the first reflective electrode RE1 through the first contact hole CT1.

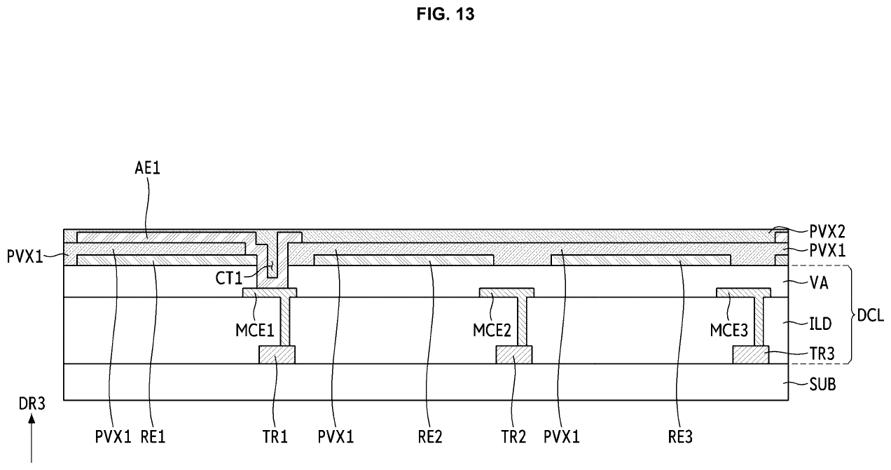

Subsequently, as illustrated in FIG. 13, the second step layer PVX2 may be formed on the first step layer PVX1 and the first anode electrode AE1. The second step layer PVX2 may be overlapped with the first reflective electrode RE1, the second reflective electrode RE2, the third reflective electrode RE3, and the first anode electrode AE1.

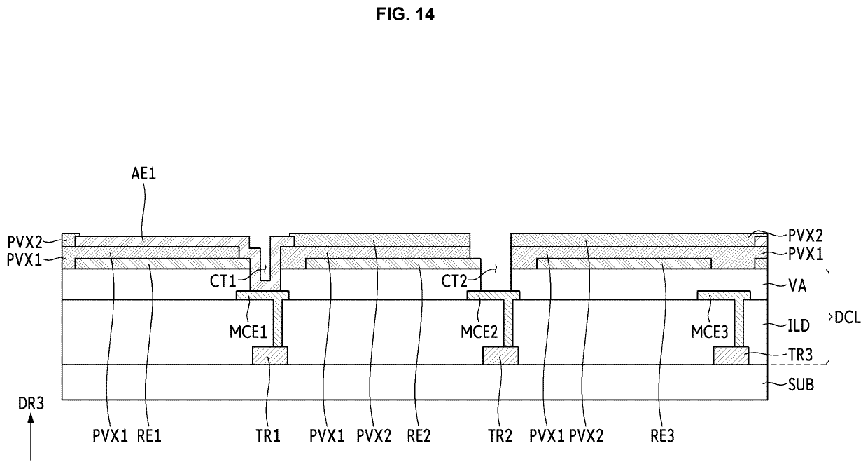

Thereafter, as illustrated in FIG. 14, the second contact hole CT2 penetrating through the second step layer PVX2, the first step layer PVX1, and the planarization layer VA may be formed. For example, the second contact hole CT2 may be formed by removing the second step layer PVX2, the first step layer PVX1, and the planarization layer VA by dry etching through a photolithography process. The upper surface of the second intermediate connection electrode MCE2, the side surface of the second reflective electrode RE2, and the upper surface of the second reflective electrode RE2 may be exposed by the second contact hole CT2. In addition, the second step layer PVX2 may be removed on the first reflective electrode RE1 through the photolithography process described above. Accordingly, as illustrated in FIG. 14, the second step layer PVX2 patterned by the photolithography process described above may be penetrated by the second contact hole CT2, and may be overlapped with the second reflective electrode RE2 and the third reflective electrode RE3 on the first step layer PVX1. For example, the patterned second step layer PVX2 does not overlap the first reflective electrode RE1 and the first anode electrode AE1, and also does not overlap the first step layer PVX1 between the first reflective electrode RE1 and the first anode electrode AE1.

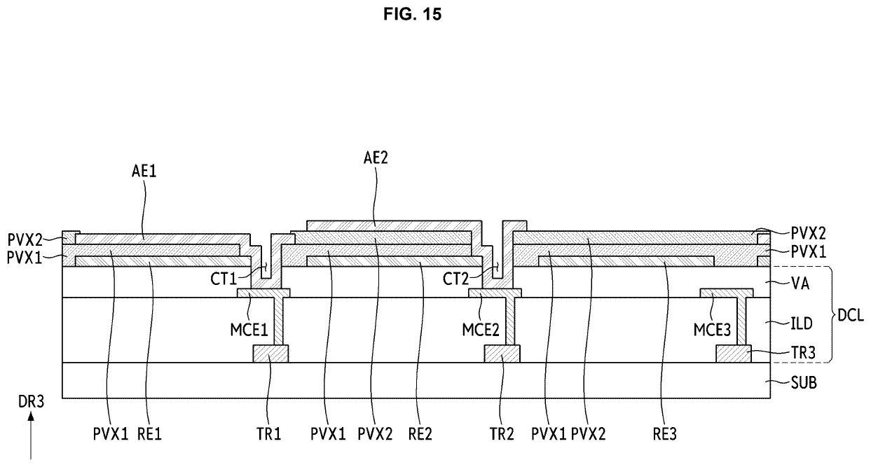

Next, as illustrated in FIG. 15, the second anode electrode AE2 may be formed on the second step layer PVX2. For example, the second anode electrode AE2 may be arranged on the second step layer PVX2 to be overlapped with the second step layer PVX2, the first step layer PVX1, and the second reflective electrode RE2. The second anode electrode AE2 may be connected to the second intermediate connection electrode MCE2 and the second reflective electrode RE2 through the second contact hole CT2. For example, the second anode electrode AE2 may be in contact (or in direct contact) with each of the upper surface of the second intermediate connection electrode MCE2, the side surface of the second reflective electrode RE2, and the upper surface of the second reflective electrode RE2 through the second contact hole CT2.

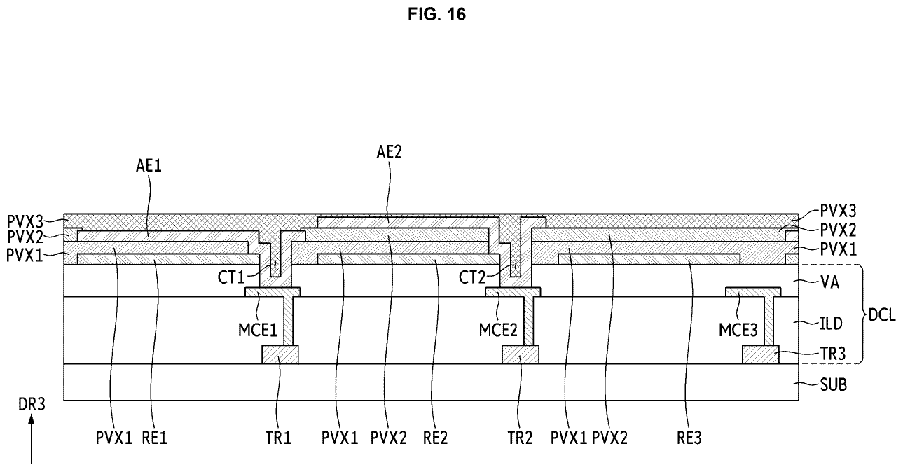

Thereafter, as illustrated in FIG. 16, the third step layer PVX3 may be formed on the second step layer PVX2, the first anode electrode AE1, and the second anode electrode AE2. The third step layer PVX3 may be overlapped with the first reflective electrode RE1, the second reflective electrode RE2, the third reflective electrode RE3, the first anode electrode AE1, and the second anode electrode AE2.

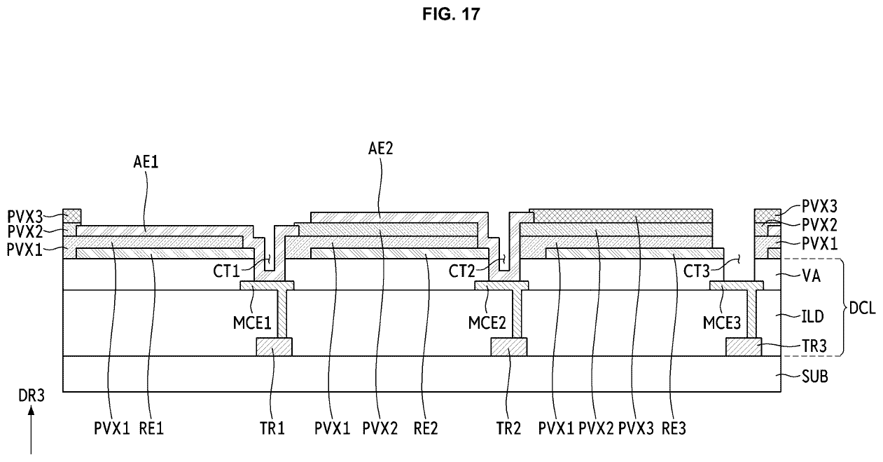

Thereafter, as illustrated in FIG. 17, the third contact hole CT3 penetrating through the third step layer PVX3, the second step layer PVX2, the first step layer PVX1, and the planarization layer VA may be formed. For example, the third contact hole CT3 may be formed by removing the third step layer PVX3, the second step layer PVX2, the first step layer PVX1, and the planarization layer VA by dry etching through a photolithography process. The upper surface of the third intermediate connection electrode MCE3, the side surface of the third reflective electrode RE3, and the upper surface of the third reflective electrode RE3 may be exposed by the third contact hole CT3. In addition, the third step layer PVX3 may be removed on the first reflective electrode RE1 and the second reflective electrode RE2 through the photolithography process described above. Accordingly, as illustrated in FIG. 17, the third step layer PVX3 patterned by the photolithography process described above may be penetrated by the third contact hole CT3, and may be overlapped with the third reflective electrode RE3 on the second step layer PVX2. For example, the patterned third step layer PVX3 does not overlap the first reflective electrode RE1, the second reflective electrode RE2, the first anode electrode AE1, and the second anode electrode AE2, does not overlap the first step layer PVX1 between the first reflective electrode RE1 and the first anode electrode AE1, and also does not overlap the first step layer PVX1 and the second step layer PVX2 between the second reflective electrode RE2 and the second anode electrode AE2.

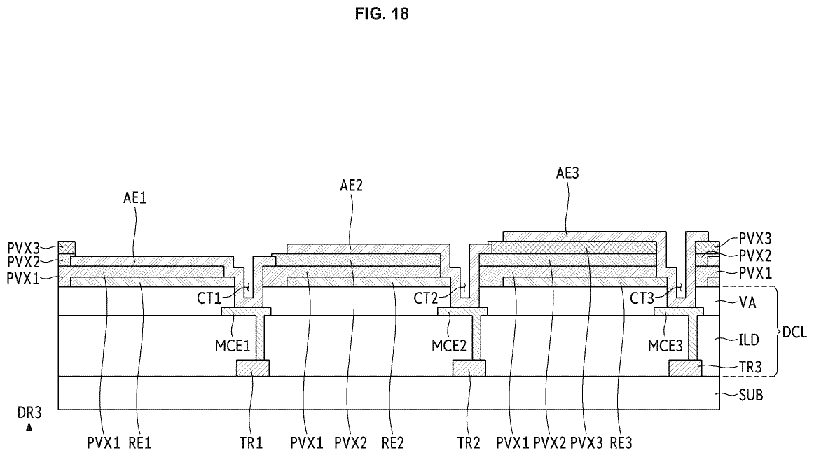

Next, as illustrated in FIG. 18, the third anode electrode AE3 may be formed on the third step layer PVX3. For example, the third anode electrode AE3 may be arranged on the third step layer PVX3 to be overlapped with the third step layer PVX3, the second step layer PVX2, the first step layer PVX1, and the third reflective electrode RE3. The third anode electrode AE3 may be connected to the third intermediate connection electrode MCE3 and the third reflective electrode RE3 through the third contact hole CT3. For example, the third anode electrode AE3 may be in contact (or in direct contact) with each of the upper surface of the third intermediate connection electrode MCE3, the side surface of the third reflective electrode RE3, and the upper surface of the third reflective electrode RE3 through the third contact hole CT3.

Thereafter, as illustrated in FIG. 5, the bank BK may be formed on the third step layer PVX3, the first anode electrode AE1, the second anode electrode AE2, and the third anode electrode AE3. Next, the light-emitting stack EL may be formed on the first anode electrode AE1, the second anode electrode AE2, the third anode electrode AE3, and the bank BK, the cathode electrode CE may be formed on the light-emitting stack EL, the encapsulation layer ENC may be formed on the cathode electrode CE, and the color filter layer CFL may be then formed on the encapsulation layer ENC.

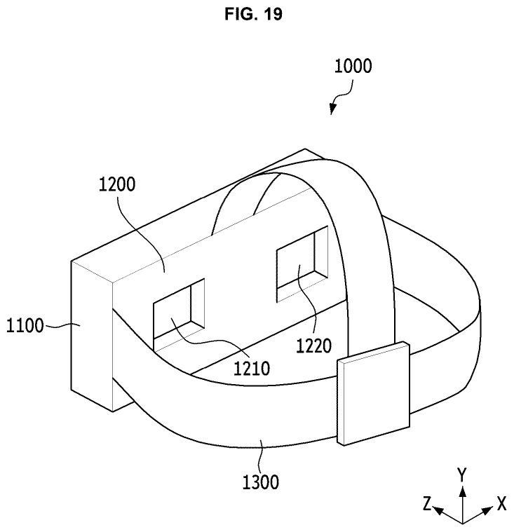

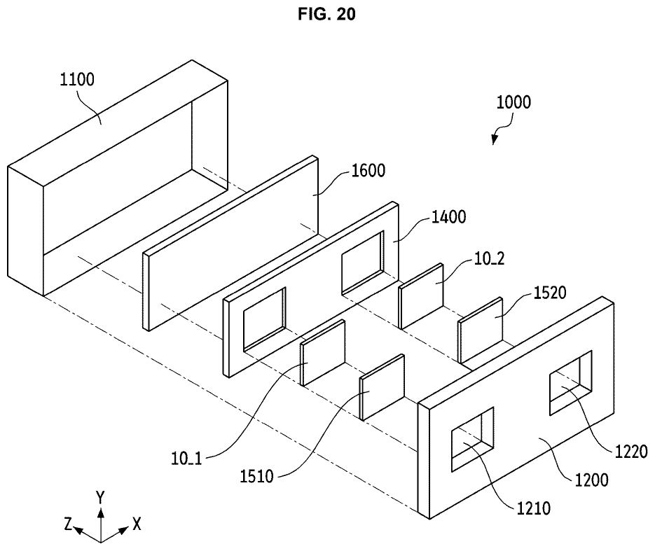

FIG. 19 is a perspective view illustrating a head-mounted display device according to one or more embodiments. FIG. 20 is an exploded perspective view illustrating an example of the head-mounted display device of FIG. 19.

Referring to FIGS. 19 and 20, a head-mounted display device 1000 according to one or more embodiments includes a first display device 10_1, a second display device 102, a display device housing portion 1100, a housing portion cover 1200, a first eyepiece 1210, a second eyepiece 1220, a head-mounted band 1300, a middle frame 1400, a first optical member 1510, a second optical member 1520, and a control circuit board 1600.

The first display device 10_1 provides an image to a user's left eye, and the second display device 102 provides an image to a user's right eye. Each of the first display device 10_1 and the second display device 10_2 is substantially the same as the display device 10 described with reference to FIGS. 1 to 18, and a description of the first display device 10_1 and the second display device 10_2 is thus not provided.

The first optical member 1510 may be arranged between the first display device 10_1 and the first eyepiece 1210. The second optical member 1520 may be arranged between the second display device 10_2 and the second eyepiece 1220.

Each of the first optical member 1510 and the second optical member 1520 may include at least one convex lens.

The middle frame 1400 may be arranged between the first display device 10_1 and the control circuit board 1600 and arranged between the second display device 10_2 and the control circuit board 1600. The middle frame 1400 serves to support and fix the first display device 10_1, the second display device 10_2, and the control circuit board 1600.

The control circuit board 1600 may be arranged between the middle frame 1400 and the display device housing portion 1100. The control circuit board 1600 may be connected to the first display device 10_1 and the second display device 10_2 through a connector. The control circuit board 1600 may be configured to convert an image source input from the outside into digital video data DATA, and transmit the digital video data DATA to the first display device 10_1 and the second display device 10_2 through the connector.

The control circuit board 1600 may be to transmit digital video data DATA corresponding to a left eye image improved or optimized for the user's left eye to the first display device 10_1 and transmit digital video data DATA corresponding to a right eye image improved or optimized for the user's right eye to the second display device 10_2. In one or more embodiments, the control circuit board 1600 may be to transmit the same digital video data DATA to the first display device 10_1 and the second display device 10_2.

The display device housing portion 1100 serves to house the first display device 10_1, the second display device 102, the middle frame 1400, the first optical member 1510, the second optical member 1520, and the control circuit board 1600. The housing portion cover 1200 covers opened one surface of the display device housing portion 1100. The housing portion cover 1200 may include the first eyepiece 1210 on which the user's left eye is arranged and the second eyepiece 1220 on which the user's right eye is arranged. It has been illustrated in FIGS. 19 and 20 that the first eyepiece 1210 and the second eyepiece 1220 are separately arranged, but one or more embodiments of the present disclosure is not limited thereto. The first eyepiece 1210 and the second eyepiece 1220 may be merged as one eyepiece.

The first eyepiece 1210 may be aligned with the first display device 10_1 and the first optical member 1510, and the second eyepiece 1220 may be aligned with the second display device 10_2 and the second optical member 1520. Accordingly, a user may view an image of the first display device 10_1 magnified as a virtual image by the first optical member 1510 through the first eyepiece 1210, and may view an image of the second display device 10_2 magnified as a virtual image by the second optical member 1520 through the second eyepiece 1220.

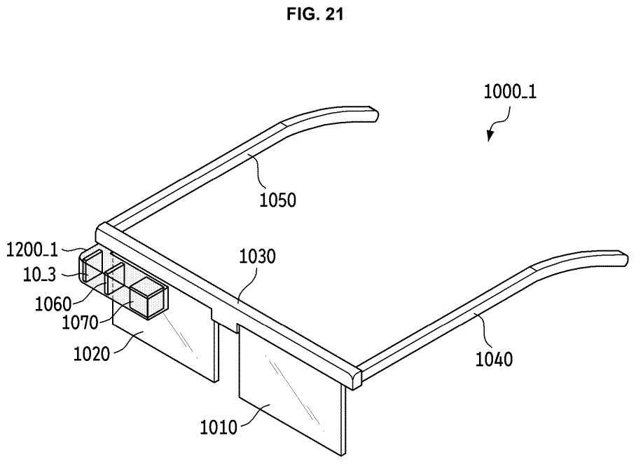

The head-mounted band 1300 serves to fix the display device housing portion 1100 to a user's head, so that the first eyepiece 1210 and the second eyepiece 1220 of the housing portion cover 1200 may be maintained in a state where the first eyepiece 1210 and the second eyepiece 1220 are arranged on the user's left eye and right eye, respectively. For example, the head-mounted band 1300 serves to fix the display device housing portion 1100 to a user's head, ensuring that the first eyepiece 1210 and the second eyepiece 1220 of the housing portion cover 1200 are maintained in a position where the first eyepiece 1210 is aligned with the user's left eye and the second eyepiece 1220 is aligned with the user's right eye. If (e.g., when) the display device housing portion 1200 is implemented to have a light weight and a small size, the head-mounted display device 1000 may include an eyeglass frame as illustrated in FIG. 21 instead of the head-mounted band 1300.

In addition, the head-mounted display device 1000 may further include a battery for supplying power, an external memory slot for housing an external memory, and an external connection port and a wireless communication device for receiving an image source. The external connection port may be a universe serial bus (USB) terminal, a display port, and/or a high-definition multimedia interface (HDMI) terminal, and the wireless communication device may be a 5G communication device, a 4G communication device, a wireless fidelity (WiFi) device, and/or a Bluetooth device.

FIG. 21 is a perspective view illustrating a head-mounted display according to one or more embodiments.

Referring to FIG. 21, a head-mounted display device 1000_1 according to one or more embodiments may be a glasses-type (kind) display device in which a display device housing portion 1200_1 is implemented to have a light weight and a small size. In one or more embodiments, the head-mounted display device 1000_1 may include a display device 103, a left eye lens 1010, a right eye lens 1020, a support frame 1030, glasses frame legs 1040 and 1050, an optical member 1060, an optical path conversion member 1070, and a display device housing portion 1200_1.

The display device housing portion 12001 may include the display device 10_3, the optical member 1060, and the optical path conversion member 1070. An image displayed on the display device 103 may be magnified by the optical member 1060, converted in an optical path by the optical path conversion member 1070, and provided to a user's right eye through the right eye lens 1020. Therefore, a user may view an augmented reality image in which a virtual image displayed on the display device 10_3 through his/her right eye and a real image seen through the right eye lens 1020 are combined with each other.

It has been illustrated in FIG. 21 that the display device housing portion 1200_1 is arranged at a right end of the support frame 1030, but one or more embodiments of the present disclosure is not limited thereto. For example, the display device housing portion 1200_1 may be arranged at a left end of the support frame 1030, and in this case, an image of the display device 10_3 may be provided to a user's left eye. In one or more embodiments, the display device housing portions 12001 may be arranged at both (e.g., simultaneously) the left and right ends of the support frame 1030, and in this case, the user may view an image displayed on the display device 10_3 through both (e.g., simultaneously) his/her left and right eyes.

In one or more embodiments, the display device 10 may be applied to one or more suitable electronic devices. In one or more embodiments, an electronic device may include the display device 10 described above, and may further include devices having other additional functions in addition to the display device 10.

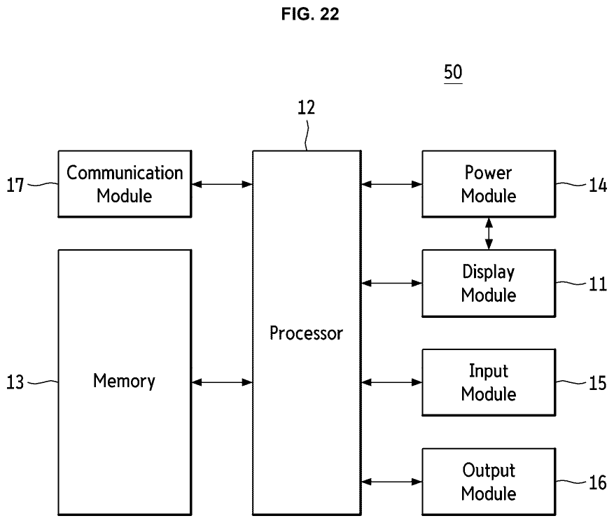

FIG. 22 is a block diagram of an electronic device according to one or more embodiments. Referring to FIG. 22, an electronic device 50 according to one or more embodiments may include a display 11, a processor 12, a memory 13, and a power device 14. The electronic device 50 may further include an input device 15, a non-image output device 16, and/or a communication device 17.

The electronic device 50 may be configured to output one or more suitable information in the form of an image through the display 11. If (e.g., when) the processor 12 executes an application stored in the memory 13, image information provided by the application may be provided to a user through the display 11. The power device 14 may include a power supply, such as a power adapter and/or a battery device, and a power conversion device converting power supplied by the power supply to generate power necessary for an operation of the electronic device 50. The input device 15 may provide input information to the processor 12 and/or the display 11. The non-image output device 16 may be configured to receive information other than an image received from the processor 12, such as sound information, haptic information, and/or light-emitting information, and provide the received information to the user. The communication device 17 is a device in charge of transmitting and receiving information between the electronic device 50 and an external device, and may include a receiving unit (e.g., a receiver) and a transmitting unit (e.g., a transmitter).

At least one of the respective components of the above-described electronic device 50 may be included in the display device according to the above-described embodiments. In addition, some of individual devices functionally included in one device may be included in the display device, and the others of the individual devices may be provided separately from the display device. For example, the display device may include the display 11, and the processor 12, the memory 13, and the power device 14 may be provided in the form of other devices within the electronic device 50 rather than the display device.

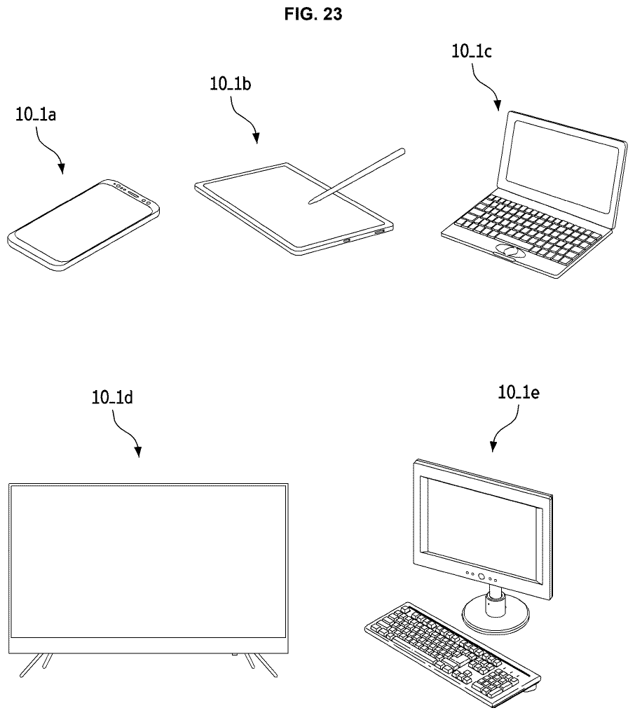

FIGS. 23 to 25 are schematic views each showing electronic devices according to one or more suitable embodiments. FIGS. 23 to 25 illustrate examples of one or more suitable electronic devices to which a display device 10 according to one or more embodiments is applied.

FIG. 23 illustrates a smartphone 10_1a, a tablet personal computer (PC) 10_1b, a laptop computer 10_1c, a television (TV) 10_1d, and a monitor 10_1e for a desktop computer as examples of the electronic devices.

The smartphone 10_1a may include an input device, such as a touch sensor and a communication device in addition to the display. The smartphone 10_1a may be configured to process information received through the communication device or other input devices and display the processed information through the display of the display device.

Each of the tablet PC 10_1b, the laptop computer 10_1c, the TV 10_1d, and the monitor 10_1e for a desktop computer may include a display and an input device, similar to the smartphone 10_1a, and may further include a communication device in one or more embodiments.

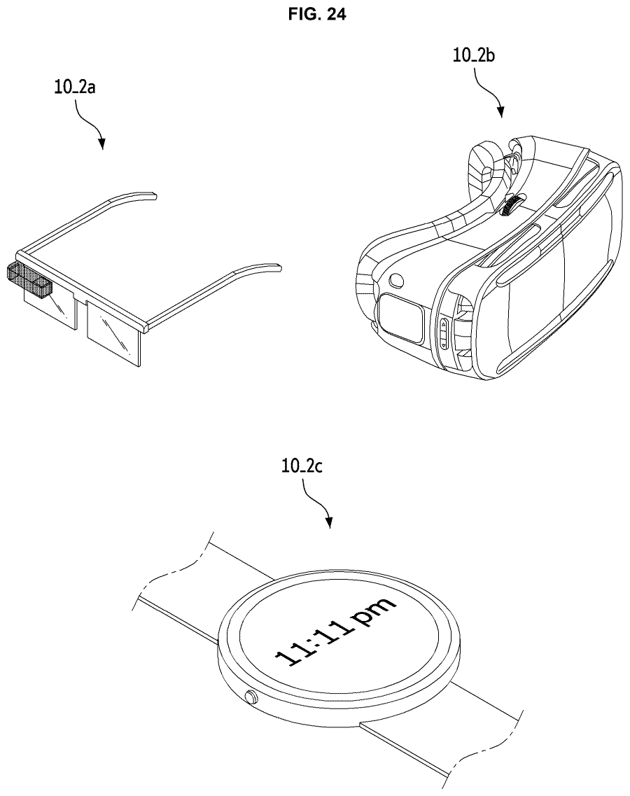

FIG. 24 illustrates one or more embodiments where an electronic device including a display is applied to a wearable electronic device. The wearable electronic device may be smart glasses 10_2a, a head-mounted display 10_2b, a smart watch 10_2c, and/or the like.

The smart glasses 10_2a and the head-mounted display 10_2b may include a display emitting a display image and a reflector reflecting the emitted display image and providing the emitted display image to user's eyes, and accordingly, may provide a virtual reality screen or an augmented reality screen to the user.

The smart watch 10_2c may include a biometric sensor as an input device, and may provide biometric information recognized through the biometric sensor to the user through the display.

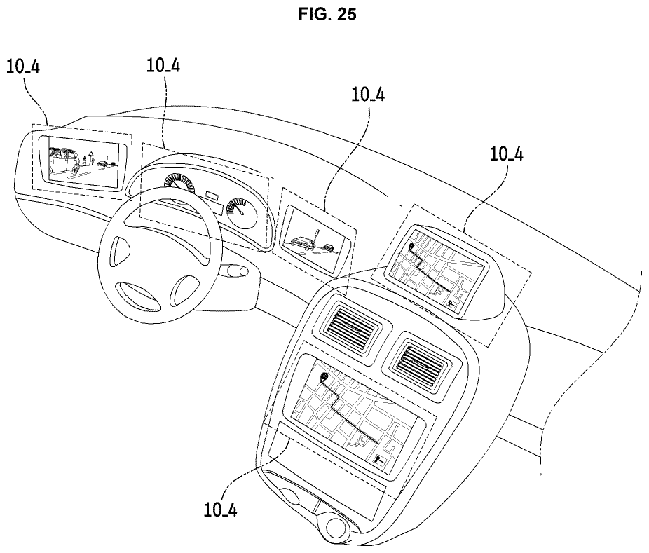

FIG. 25 illustrates one or more embodiments where an electronic device including a display is applied to a vehicle. For example, an electronic device 10_4 may be applied to an instrument board, a center fascia, and/or the like, of the vehicle or applied to a center information display (CID) arranged on a dashboard of the vehicle, a room mirror display substituting for a side-view mirror, and/or the like.

In summary, the present disclosure enhances the efficiency (e.g., improved aperture ratio of the pixel, lighter weight, and/or smaller size) of the display device by reducing the number of contact holes for connecting electrodes according to one or more embodiments of the present disclosure.

For example, a reflective electrode constitutes a portion of an inner wall of a contact hole, and thus, a reflective electrode, an anode electrode, and an intermediate connection electrode may be connected through only one contact hole. Accordingly, the number of contact holes for connecting the above electrodes may be reduced, such that an aperture ratio of the pixel may be improved.

In addition, anode electrodes are arranged at different heights on different layers, therefore, the anode electrodes may be arranged more closely in a horizontal direction, such that the size of the display device may be reduced, or an area of the anode electrode and an area of an emission area may be expanded in the horizontal direction. Accordingly, an aperture ratio of the pixel may be increased which allows more light to emit, and therefore, a high-resolution display device may be implemented.

As used herein, the terms “substantially,” “about,” and similar terms are used as terms of approximation and not as terms of degree, and are intended to account for the inherent deviations in measured or calculated values that would be recognized by those of ordinary skill in the art. “About” or “approximately,” as used herein, is also inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

In the context of the present disclosure and unless otherwise defined, the terms “use,” “using,” and “used” may be considered synonymous with the terms “utilize,” “utilizing,” and “utilized,” respectively.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

The display apparatus/device, the electronic apparatus/device, the manufacturing apparatuses thereof, or any other relevant apparatuses/devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

The utilization of “may” when describing embodiments of the present disclosure refers to “one or more embodiments of the present disclosure.”

In concluding the detailed description, those skilled in the art will appreciate that many variations and modifications may be made to one or more embodiments of the present application without substantially departing from the principles of disclosure. Therefore, the disclosed embodiments of present disclosure are utilized in a generic and descriptive sense only and not for purposes of limitation.

While one or more embodiments of the present disclosure have been described above, a person ordinarily skilled in the art to which the present disclosure pertains shall appreciate that there may be a variety of modifications and permutations of the present disclosure without departing from the technical ideas and scopes of the present disclosure and equivalents thereof that are defined in the appended claims. Moreover, it shall be appreciated that the one or more embodiments of the present disclosure are not intended to restrict the present disclosure thereto and that every technical idea within the appended claims and their equivalents is interpreted to be included in the scope of the present disclosure and equivalents thereof.

What is claimed is:

1. A display device comprising:
a substrate;
a first intermediate connection electrode, a second intermediate connection electrode, and a third intermediate connection electrode on the substrate;
a planarization layer on the first intermediate connection electrode, the second intermediate connection electrode, and the third intermediate connection electrode;
a first reflective electrode, a second reflective electrode, and a third reflective electrode on the planarization layer;
a first step layer on the first reflective electrode, the second reflective electrode, and the third reflective electrode;
a first anode electrode on the first step layer overlapping the first reflective electrode;
a bank on the first anode electrode;
a light-emitting stack on the first anode electrode and the bank; and
a cathode electrode on the light-emitting stack,
wherein the first anode electrode is in contact with an upper surface of the first intermediate connection electrode, an upper surface of the first reflective electrode, and a side surface of the first reflective electrode through a first contact hole penetrating through the first step layer and the planarization layer.

2. The display device of claim 1, wherein in plan view, the first contact hole is surrounded and defined by the planarization layer, the first step layer, and the first reflective electrode.

3. The display device of claim 1, wherein
the first contact hole has a first width on a lower side of the first reflective electrode, and
the first contact hole has a second width on an upper side of the first reflective electrode,
the second width being greater than the first width.

4. The display device of claim 1, further comprising:
a second step layer on the first step layer overlapping the second reflective electrode and the third reflective electrode; and
a second anode electrode on the second step layer overlapping the second reflective electrode and the first step layer,
wherein the second anode electrode is in contact with an upper surface of the second intermediate connection electrode, an upper surface of the second reflective electrode, and a side surface of the second reflective electrode through a second contact hole penetrating through the second step layer, the first step layer, and the planarization layer.

5. The display device of claim 4, wherein in plan view, the second contact hole is surrounded and defined by the planarization layer, the first step layer, the second step layer, and the second reflective electrode.

6. The display device of claim 4, further comprising:
a third step layer on the second step layer overlapping the third reflective electrode; and
a third anode electrode on the third step layer overlapping the third reflective electrode, the first step layer, and the second step layer,
wherein the third anode electrode is in contact with an upper surface of the third intermediate connection electrode, an upper surface of the third reflective electrode, and a side surface of the third reflective electrode through a third contact hole penetrating through the third step layer, the second step layer, the first step layer, and the planarization layer.

7. The display device of claim 6, wherein in plan view, the third contact hole is surrounded and defined by the planarization layer, the first step layer, the second step layer, the third step layer, and the third reflective electrode.

8. The display device of claim 6, wherein the first contact hole, the second contact hole, and the third contact hole have different depths.

9. The display device of claim 8, wherein a depth of the second contact hole is greater than a depth of the first contact hole and smaller than a depth of the third contact hole.

10. The display device of claim 6, wherein a distance from the first reflective electrode to the cathode electrode, a distance from the second reflective electrode to the cathode electrode, and a distance from the third reflective electrode to the cathode electrode are different from each other.

11. The display device of claim 10, wherein
the distance from the second reflective electrode to the cathode electrode is greater than the distance from the first reflective electrode to the cathode electrode, and
the distance from the second reflective electrode to the cathode electrode is smaller than the distance from the third reflective electrode to the cathode electrode.

12. The display device of claim 11, further comprising:
a first color filter overlapping the first anode electrode and the first reflective electrode;
a second color filter overlapping the second anode electrode and the second reflective electrode; and
a third color filter overlapping the third anode electrode and the third reflective electrode.

13. The display device of claim 12, wherein
the first color filter is configured to selectively transmit light of a red wavelength,
the second color filter is configured to selectively transmit light of a green wavelength, and
the third color filter is configured to selectively transmit light of a blue wavelength.

14. The display device of claim 6, wherein the first anode electrode, the second anode electrode, and the third anode electrode are at different heights on the planarization layer.

15. The display device of claim 12, wherein
a distance from the planarization layer to the second anode electrode is greater than a distance from the planarization layer to the first anode electrode, and
the distance from the planarization layer to the second anode electrode is smaller than a distance from the planarization layer to the third anode electrode.

16. The display device of claim 6, wherein the first anode electrode, the second anode electrode, and the third anode electrode have the same thickness.

17. The display device of claim 6, wherein the first step layer, the second step layer, and the third step layer have the same thickness.

18. A method, comprising:
forming a first intermediate connection electrode, a second intermediate connection electrode, and a third intermediate connection electrode on a substrate;
forming a planarization layer on the first intermediate connection electrode, the second intermediate connection electrode, and the third intermediate connection electrode;
forming a first reflective electrode, a second reflective electrode, and a third reflective electrode on the planarization layer;
forming a first step layer on the first reflective electrode, the second reflective electrode, and the third reflective electrode;
forming a first contact hole by patterning the first step layer and the planarization layer, the first contact hole exposing an upper surface of the first intermediate connection electrode, an upper surface of the first reflective electrode, and a side surface of the first reflective electrode;
forming a first anode electrode on the first step layer, the first anode electrode being in contact with the upper surface of the first intermediate connection electrode, the upper surface of the first reflective electrode, and the side surface of the first reflective electrode through the first contact hole;
forming a bank on the first anode electrode;
forming a light-emitting stack on the first anode electrode and the bank; and
forming a cathode electrode on the light-emitting stack,
wherein the method is a method for manufacturing a display device.

19. An electronic device comprising a display device providing a display screen,
wherein the display device comprises:
a substrate;
a first intermediate connection electrode, a second intermediate connection electrode, and a third intermediate connection electrode on the substrate;
a planarization layer on the first intermediate connection electrode, the second intermediate connection electrode, and the third intermediate connection electrode;
a first reflective electrode, a second reflective electrode, and a third reflective electrode on the planarization layer;
a first step layer on the first reflective electrode, the second reflective electrode, and the third reflective electrode;
a first anode electrode on the first step layer overlapping the first reflective electrode;
a bank on the first anode electrode;
a light-emitting stack on the first anode electrode and the bank; and
a cathode electrode on the light-emitting stack, and
the first anode electrode is in contact with an upper surface of the first intermediate connection electrode, an upper surface of the first reflective electrode, and a side surface of the first reflective electrode through a first contact hole penetrating through the first step layer and the planarization layer.

20. The electronic device of claim 19, wherein the electronic device comprises a smartphone, a tablet personal computer (PC), a laptop computer, a television (TV), a monitor for a desktop computer, smart glasses, a smart watch, a head-mounted display, and/or a vehicle.
